(19) United States
(12) Patent Application Publication
(10) Pub. No.: US 2025/0287573 A1
(43) Pub. Date: Sep. 11, 2025

(54) SEMICONDUCTOR DEVICE

(71) Applicant: Samsung Electronics Co., Ltd., Suwon-si (KR)

(72) Inventor: Bohyun Kim, Suwon-si (KR)

(73) Assignee: Samsung Electronics Co., Ltd., Suwon-si (KR)

(21) Appl. No.: 19/008,323

(22) Filed: Jan. 2, 2025

(30) Foreign Application Priority Data
Mar. 8, 2024 (KR) 10-2024-0033144

(51) Int. Cl. H10B 12/00

(52) U.S. Cl. CPC H10B 12/485; H10B 12/02

(57) ABSTRACT

A semiconductor device may include a first insulating interlayer on a substrate, first contact plugs passing through the first insulating interlayer, a second insulating interlayer on the first insulating interlayer and first contact plugs, and first conductive patterns passing through the second insulating interlayer and extending below an upper surface of the first insulating interlayer in a vertical direction. Each first contact plug may include a first metal pattern and a first barrier metal pattern covering a portion of a sidewall of the first metal pattern, further covering a bottom of the first metal pattern, and further exposing an upper sidewall of the first metal pattern. Each of the first conductive patterns may have a first bottom surface contacting a portion of an upper surface of a respective first contact plug, and a second bottom surface contacting the first insulating interlayer and being lower than the first bottom surface.

### CROSS-REFERENCE TO RELATED APPLICATION

This application claims priority under 35 USC § 119(a) to Korean Patent Application No. 10-2024-0033144, filed on Mar. 8, 2024, in the Korean Intellectual Property Office (KIPO), the contents of which are incorporated by reference herein in their entirety.

### BACKGROUND

Various example embodiments relate to a semiconductor device. Particularly, various example embodiments relate to a semiconductor device having high reliability.

Interconnection structures for electrically connecting circuit patterns to each other may be included in a semiconductor device. An interconnection structure may include a contact plug and a conductive pattern on the contact plug. As physical dimensions of the contact plug and the conductive pattern are becoming smaller, less space is present between the contact plug and conductive patterns adjacent to the contact plug in a horizontal direction. Accordingly, insulation breakdown of insulation material between the contact plug and the conductive pattern may occur, so that a reliability of the semiconductor device may be decreased.

### SUMMARY

Various example embodiments provide a semiconductor device including an interconnection structure having high reliability.

According to some example embodiments, there is provided a semiconductor device. The semiconductor device may include a substrate, a first insulating interlayer on the substrate, a plurality of first contact plugs passing through the first insulating interlayer, a second insulating interlayer that is on the first insulating interlayer and is further on the plurality of first contact plugs, and a plurality of first conductive patterns passing through the second insulating interlayer and extending below an upper surface of the first insulating interlayer in a vertical direction. Each of the plurality of first contact plugs may include a first metal pattern and a first barrier metal pattern covering a portion of a sidewall of the first metal pattern and further covering a bottom of the first metal pattern, and the first barrier metal pattern further exposing an upper sidewall of the first metal pattern. Each of the plurality of first conductive patterns may have a first bottom surface contacting a portion of an upper surface of a respective first contact plug of the plurality of first contact plugs, and a second bottom surface contacting the first insulating interlayer and being lower than the first bottom surface.

According to some example embodiments, there is provided a semiconductor device. The semiconductor device may include a substrate, a first insulating interlayer on the substrate, a plurality of first contact plugs, a second insulating interlayer that is on the first insulating interlayer and is further on the plurality of first contact plugs, and a plurality of first conductive patterns passing through the second insulating interlayer and extending below an upper surface of the first insulating interlayer in a vertical direction. The first insulating interlayer may include a plurality of contact holes. The plurality of first contact plugs may be in the plurality of contact holes, respectively. Each of the plurality of first contact plugs may include a first metal pattern and a first barrier metal pattern covering a portion of a sidewall of the first metal pattern and further covering a bottom of the first metal pattern. An uppermost surface of the first barrier metal pattern may be lower than an upper surface of the first metal pattern. Each of the plurality of first conductive patterns may contact an upper surface of a respective first contact plug of the plurality of first contact plugs and may further contact a respective upper portion of the first insulating interlayer. A distance in a horizontal direction between an uppermost sidewall of the first metal pattern of the respective first contact plug and the first conductive pattern may be greater than a distance in the horizontal direction between an uppermost sidewall of the first barrier metal pattern of the respective first contact plug and the first conductive pattern.

According to some example embodiments, there is provided a semiconductor device. The semiconductor device may include a substrate, a plurality of capacitors on a cell region of the substrate, a plurality of peripheral circuit patterns on a peripheral circuit region of the substrate, a first insulating interlayer covering the plurality of capacitors and further covering the plurality of peripheral circuit patterns, a plurality of first contact plugs passing through the first insulating interlayer and connecting to the plurality of peripheral circuit patterns, a second insulating interlayer that is on the first insulating interlayer and is further on the plurality of first contact plugs, and a first conductive pattern passing through the second insulating interlayer and extending below an upper surface of the first insulating interlayer in a vertical direction. Each of the plurality of first contact plugs may include a first metal pattern and a first barrier metal pattern covering a portion of a sidewall of the first metal pattern and further covering a bottom of the first metal pattern and the first barrier metal pattern further exposing an upper sidewall of the first metal pattern. The first conductive pattern may contact upper surfaces of the plurality of first contact plugs and further contact an upper surface of the first insulating interlayer on the peripheral circuit region. A distance in a horizontal direction between an uppermost sidewall of the first metal pattern of a first contact plug of the plurality of first contact plugs and the first conductive pattern may be greater than a distance in the horizontal direction between an uppermost sidewall of the first barrier metal pattern of the first contact plug and the first conductive pattern.

According to example embodiments, in the interconnection structure, a minimum distance in a horizontal direction between the contact plug and the conductive pattern adjacent to the contact plug may be increased. Accordingly, insulation breakdown between the contact plug and the conductive pattern may be decreased, so that the interconnection structure may have high reliability.

### BRIEF DESCRIPTION OF THE DRAWINGS

Various example embodiments will be more clearly understood from the following detailed description taken in conjunction with the accompanying drawings. FIGS. 1A to 35 represent various non-limiting, example embodiments as described herein.

FIG. 1A is a cross-sectional view of an interconnection structure of a semiconductor device according to example embodiments;

FIG. 1B is a cross-sectional view of an interconnection structure of a semiconductor device according to example embodiments;

FIG. 1C is a cross-sectional view of an interconnection structure of a semiconductor device according to example embodiments;

FIG. 2 is a plan view of an interconnection structure of a semiconductor device according to example embodiments;

FIG. 3 is an enlarged cross-sectional view of a portion (i.e. portion C) of FIG. 1A;

FIG. 4 is an enlarged cross-sectional view of a portion of an interconnection structure of a semiconductor device according to some example embodiments;

FIG. 5 is an enlarged cross-sectional view of a portion of an interconnection structure of a semiconductor device according to some example embodiments;

FIGS. 6 to 15 are cross-sectional views illustrating a method of manufacturing an interconnection structure of a semiconductor device according to example embodiments;

FIG. 16 is a cross-sectional view of an interconnection structure of a semiconductor device according to example embodiments;

FIG. 17 is an enlarged cross-sectional view of a portion of FIG. 16;

FIG. 18 is a cross-sectional view of a semiconductor device according to example embodiments;

FIG. 19 is a cross-sectional view of a semiconductor device according to some example embodiments;

FIGS. 20 to 34 are cross-sectional views illustrating a method of manufacturing a semiconductor device according to example embodiments; and

FIG. 35 is a cross-sectional view of a semiconductor device according to example embodiments.

### DETAILED DESCRIPTION

Hereinafter, various example embodiments will be described in detail with reference to the accompanying drawings.

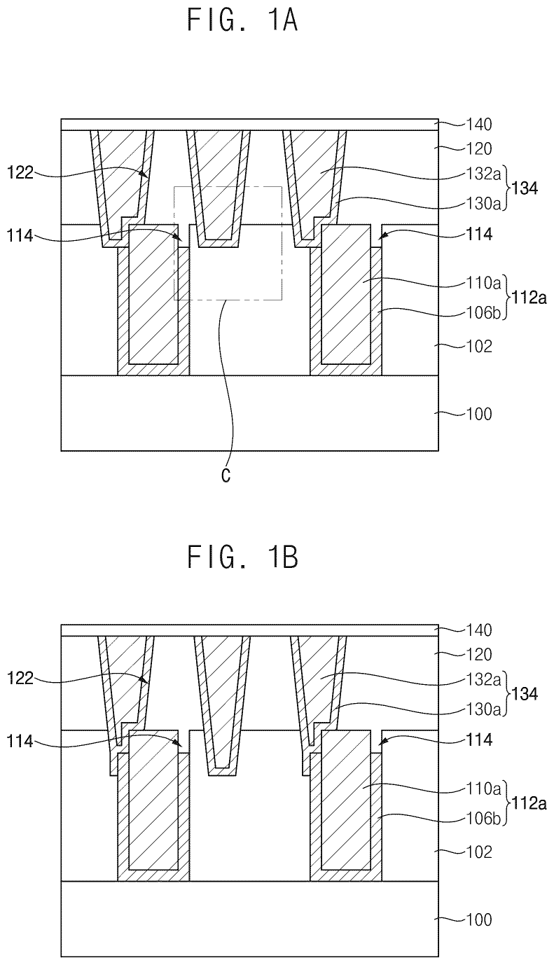

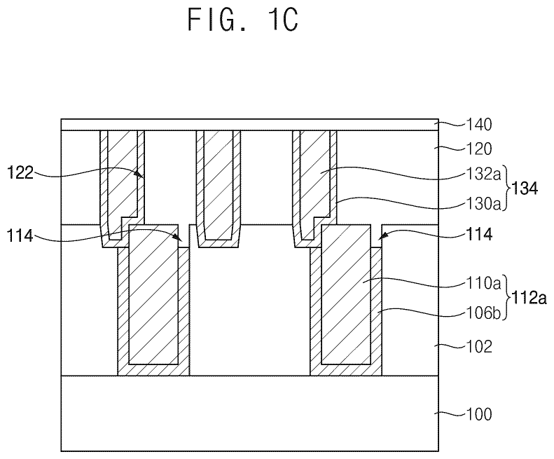

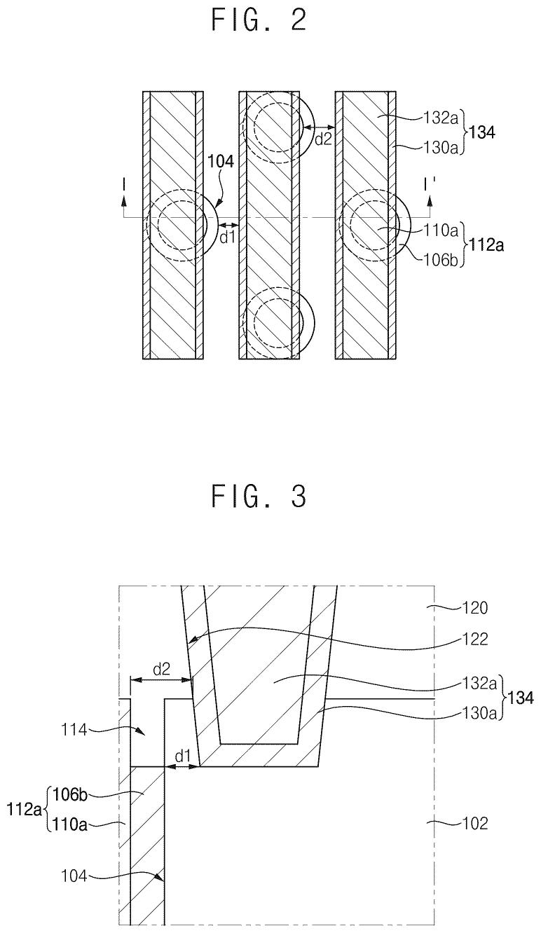

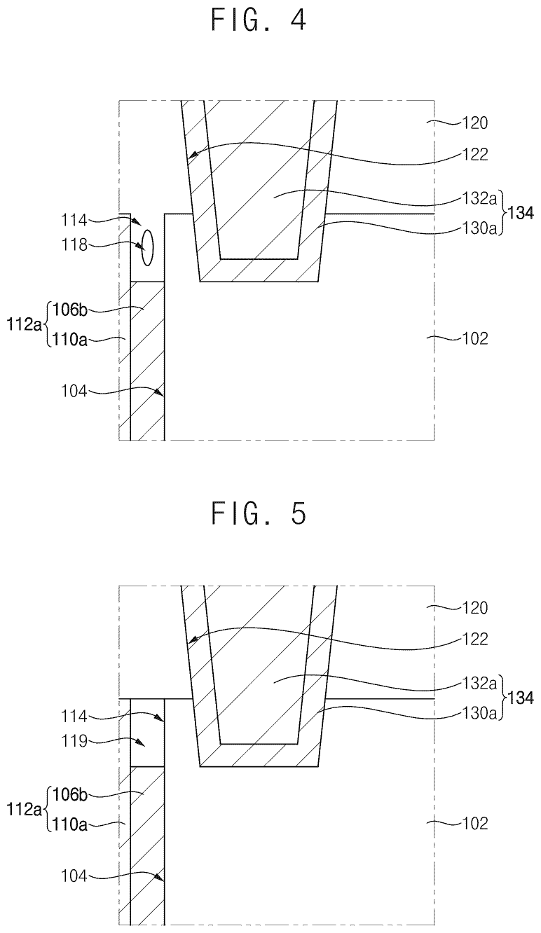

FIG. 1A is a cross-sectional view of an interconnection structure of a semiconductor device according to example embodiments. FIG. 1B is a cross-sectional view of an interconnection structure of a semiconductor device according to example embodiments. FIG. 1C is a cross-sectional view of an interconnection structure of a semiconductor device according to example embodiments. FIG. 2 is a plan view of an interconnection structure of a semiconductor device according to example embodiments. FIG. 3 is an enlarged cross-sectional view of a portion (i.e. portion C) of FIG. 1A. FIG. 4 is an enlarged cross-sectional view of a portion of an interconnection structure of a semiconductor device according to some example embodiments. FIG. 5 is an enlarged cross-sectional view of a portion of an interconnection structure of a semiconductor device according to some example embodiments.

Each of FIGS. 1A, 1B, and 1C is a cross-sectional view taken along line I-I′ of FIG. 2. The interconnection structures shown in FIGS. 4 and 5 may be substantially the same as the interconnection structure shown in FIG. 1A, except for materials occupying a first recess or a shape of the materials occupying the first recess.

Referring to FIGS. 1A, 1B, 1C, 2, and 3, a first insulating interlayer 102 may be on a substrate 100. In example embodiments, the first insulating interlayer 102 may include a silicon oxide-based material. For example, the first insulating interlayer 102 may include Tetra Ethyl Ortho Silicate (TEOS).

First contact holes 104 may pass through the first insulating interlayer 102, and may expose a surface of the substrate 100. In example embodiments, the surface of the substrate 100 may be exposed by bottoms of the first contact holes 104. In some example embodiments, a lower conductive structure may be further on the substrate 100, and the lower conductive layer may be exposed by bottoms of the first contact holes 104.

In example embodiments, in a plan view, each of the first contact holes 104 may have a circular shape or an oval shape.

A first contact plug 112a may be included for each of the first contact holes 104, each first contact plug 112b being in a respective one of the first contact holes 104. The first contact plugs 112a may pass through the first insulating interlayer 102. In example embodiments, bottoms of the first contact plugs 112a may contact the surface of the substrate 100. In some example embodiments in which a lower conductive structure is further on the substrate 100, the bottoms of the first contact plugs 112a may contact the lower conductive structure.

The first contact plugs 112a may each include a first barrier metal pattern 106b and a first metal pattern 110a. The first barrier metal pattern 106b may cover a portion of a sidewall of the first metal pattern 110a and further cover a bottom of the first metal pattern 110a.

The first barrier metal pattern 106b may conform to the portion of the sidewall of the first metal pattern 110a and further to the bottom of each of the first contact holes 104. In example embodiments, the first barrier metal pattern 106b on the portion of the sidewall of the first metal pattern 110a and on the bottom of each of the first contact holes 104 may have a uniform thickness. The first metal pattern 110a may be on the first barrier metal pattern 106b to occupy the first contact hole 104. Accordingly, the first barrier metal pattern 106b may surround the portion of the sidewall of the first metal pattern 110a and may further surround the bottom of the first metal pattern 110a.

An upper surface of the first metal pattern 110a may be substantially coplanar with an upper surface of the first insulating interlayer 102. An uppermost surface of the first barrier metal pattern 106b may be lower than the upper surface of the first metal pattern 110a. The first barrier metal pattern 106b may not be on an upper sidewall of the first metal pattern 110a. An upper sidewall of the first metal pattern 110a may be exposed by the first barrier metal pattern 106b. The first barrier metal pattern 106b may not be disposed between the upper sidewall of the first metal pattern 110a and the first insulating interlayer 102.

A first recess 114 may be between the upper sidewall of the first metal pattern 110a and the first insulating interlayer 102, and the first recess 114 may surround the upper sidewall of the first metal pattern 110a. The first recess 114 may be disposed above the uppermost surface of the first barrier metal pattern 106b.

In example embodiments, a sidewall of the first contact hole 104 may have a vertical slope, or may have a sidewall slope such that an inner width of the first contact hole 104 decreases from upper portion to the bottom thereof. Accordingly, a sidewall of the first contact plug 112a may have the vertical slope, or may have a sidewall slope such that a width of the first contact plug 112a decreases from upper portion to the bottom thereof.

In example embodiments, the first barrier metal pattern 106b may include, e.g., titanium, titanium nitride, tantalum, tantalum nitride, or tungsten nitride.

In example embodiments, the first metal pattern 110a may include tungsten. In some example embodiments, the first metal pattern 110a may include aluminum, copper, ruthenium, cobalt, nickel, palladium, platinum, silver, or gold.

A second insulating interlayer 120 may occupy the first recess 114, and may cover upper surfaces of the first contact plugs 112a and of the first insulating interlayer 102. The second insulating interlayer 120 may include a silicon oxide-based material. The second insulating interlayer 120 may include a material having a dielectric constant lower than a dielectric constant of the first insulating interlayer 102. The second insulating interlayer 120 may include a low-K insulation material. For example, the second insulating interlayer 120 may include SiOC or SiOF. The same insulation material (e.g., the second insulating interlayer) may be in the first recess 114, on the first insulating interlayer 102, and on the first contact plug 112a. For example, the first recess 114 may not be occupied with nitride, such as silicon nitride.

In example embodiments, as shown in FIGS. 1A, 1B, 1C, and 3, voids may not be included in the second insulating interlayer 120 inside the first recess 114. In some example embodiments, as shown in FIG. 4, a void 118 may be included in in the second insulating interlayer 120 inside the first recess 114.

In some example embodiments, as shown in FIG. 5, the first recess 114 may not be occupied with the second insulating interlayer 120 therein, so that the first recess 114 may remain as a space including, e.g., air 119. In this case, the second insulating interlayer 120 may disposed on the first insulating interlayer 102 and on the first contact plug 112a to cover an inlet portion of the first recess 114.

Openings 122 may pass through the second insulating interlayer 120, and may extend below the upper surface of the first insulating interlayer 102 in a vertical direction (i.e., a direction perpendicular to the upper surface of the substrate 100). The first contact plug 112a may be exposed by at least a lower portion of each of the openings 122. Each of the openings 122 may have a sidewall slope such that an inner width of each of the openings 122 decreases from an upper portion to a bottom thereof. Each of the openings 122 may have a lower width that is less than an upper width.

A first conductive pattern 134 may be in each of the openings 122. The first conductive pattern 134 may pass through the second insulating interlayer 120, and may extend below the upper surface of the first insulating interlayer 102.

A first bottom portion of the first conductive pattern 134 may contact the upper surface of the first contact plug 112a. A second bottom portion of the first conductive pattern 134 may contact the first insulating interlayer 102.

In example embodiments, the first conductive pattern 134 may not entirely cover the upper surface of a first contact plug 112a, but may partially cover the upper surface of a first contact plug 112a. In example embodiments, a lower portion of the first conductive pattern 134 may contact the upper surface of the first metal pattern 110a and further contact an upper sidewall of the first metal pattern 110a, included in the first contact plug 112a, and the lower portion of the first conductive pattern 134 may further contact an upper surface of the first barrier metal pattern 106b. In example embodiments, a portion of the first conductive pattern 134 may be disposed in a region corresponding to but opposite from the first recess 114 relative to, e.g., the first contact plug 112a. The first bottom portion of the first conductive pattern 134 may be higher than the second bottom portion of the first conductive pattern 134. In example embodiments, the first bottom portion of the first conductive pattern 134 may be substantially coplanar with the upper surface of the first metal pattern 110a of the first contact plug 112a. The second bottom portion of the first conductive pattern 134 may be lower than the upper surface of the first insulating interlayer 102, and the second bottom portion further may be higher than a bottom of the first insulating interlayer 102. The second bottom portion of the first conductive pattern 134 may be at an inner portion of the first insulating interlayer 102.

In example embodiments, as shown in FIGS. 1A and 1C, the second bottom portion of the first conductive pattern 134 may be substantially coplanar with a bottom of the first recess 114. The second bottom portion of the first conductive pattern 134 may be substantially coplanar with the uppermost surface of the first barrier metal pattern 106b. In some example embodiments, as shown in FIG. 1B, the second bottom portion of the first conductive pattern 134 may be lower than the bottom of the first recess 114. The second bottom portion of the first conductive pattern 134 may be lower than the uppermost surface of the first barrier metal pattern 106b.

The first conductive pattern 134 may include a second barrier metal pattern 130a and a second metal pattern 132a. The second barrier metal pattern 130a may cover a sidewall of the second metal pattern 132a and may further cover a bottom of the second metal pattern 132a.

The second barrier metal pattern 130a may conform to the sidewall of the opening 122 and to the bottom of the opening 122. In example embodiments, the second barrier metal pattern 130a on the sidewall and on the bottom of the opening 122 may have a uniform thickness. In some example embodiments, the second barrier metal pattern 130a on the bottom of the opening 122 may have a thickness greater than a thickness of the second barrier metal pattern 130a on the sidewall of the opening 122.

The second metal pattern 132a may be on the second barrier metal pattern 130a to occupy the opening 122.

Upper surfaces of the second metal pattern 132a and of the second barrier metal pattern 130a may be substantially coplanar with an upper surface of the second insulating interlayer 120.

In example embodiments, the second barrier metal pattern 130a may include titanium, titanium nitride, tantalum, tantalum nitride, tungsten nitride, or the like. The second metal pattern 132a may include, e.g., copper. In some example embodiments, the second metal pattern 132a may include aluminum, ruthenium, cobalt, nickel, palladium, platinum, silver, gold or the like.

In the first conductive pattern 134, a portion lower than the upper surface of the first insulating interlayer 102 is referred to within the following disclosure as a first portion of the first conductive pattern 134, and a portion higher than the upper surface of the first insulating interlayer is referred to within the following disclosure as a second portion of the first conductive pattern 134. In the claims, the recitation of a “first portion” or a “second portion” without more is not intended to incorporate these definitions therein. The first portion of the first conductive pattern 134 may contact the first insulating interlayer 102 without contacting the upper surface of the first contact plug 112a.

A width of an uppermost portion of the first conductive pattern 134 may be greater than a width of a lowermost portion of the first conductive pattern 134. At least the first portion of the first conductive pattern 134 may have a sidewall slope such that the width of first conductive pattern 134 gradually decreases downward.

In example embodiments, as shown in FIGS. 1A and 1B, the first conductive pattern 134 may have the sidewall slope such that the width of the first conductive pattern 134 gradually decreases from the uppermost portion of the first conductive pattern 134 to the lowermost portion of the first conductive pattern 134. The sidewall slope of the first conductive pattern 134 may be constant. In some example embodiments, as shown in FIG. 1C, an upper sidewall of the first conductive pattern 134 may have a vertical slope, and a lower sidewall of the first conductive pattern 134 may have a slope such that the width of first conductive pattern 134 gradually decreases downward.

In example embodiments, a portion of at least one first conductive pattern contacting the first insulating interlayer 102 may be disposed between portions of two first conductive patterns 134 contacting the upper surface of the first contact plug 112a. The first portion of the first conductive pattern 134 may be disposed adjacent to the first contact plug 112a while being spaced apart from the first contact plug 112a. In a cross-sectional view, an upper sidewall of the first contact plug 112a and the first portion of the first conductive pattern 134 may face toward each other in a horizontal direction with respect to the upper surface of the substrate.

In example embodiments, an upper portion of the first portion of the first conductive pattern 134 may face the sidewall of the first metal pattern 110a, and a lower portion of the first portion of the first conductive pattern 134 may face a sidewall of the first barrier metal pattern 106b. In some example embodiments, the first portion of the first conductive pattern 134 may face only the sidewall of the first metal pattern 110a.

A distance d2 in the horizontal direction between an uppermost sidewall of the first metal pattern 110a and the first conductive pattern 134 may be greater than a distance d1 in the horizontal direction between an uppermost sidewall of the first barrier metal pattern 106b and the first conductive pattern 134

The first and second insulating interlayers 102 and 120 may be laterally disposed between the uppermost sidewall of the first contact plug 112a and the first portion of the first conductive pattern 134.

The second insulating interlayer 120 and the first insulating interlayer 102 may be disposed in the horizontal direction between the sidewall of the first metal pattern 110a positioned higher than the uppermost surface of the first barrier metal pattern 106b and the first portion of the first conductive pattern 134. Only the first insulating interlayer 102 may be disposed between the sidewall of the first barrier metal pattern 106b and the first portion of the first conductive pattern 134.

In the following disclosure, the distance in the horizontal direction between the uppermost sidewall of the first barrier metal pattern 106b and the first conductive pattern 134 is referred to as the first distance d1. A portion having the first distance is referred to in the following disclosure as a third portion. In the claims, the recitation of a “first distance” or a “third portion” without more is not intended to incorporate these definitions therein. A third portion may be a weak region where insulation breakdown of insulation material between the first contact plug 112a and the first conductive pattern 134 easily occurs. Therefore, the weak region may compromise the reliability of the semiconductor device. In order to improve reliability of the semiconductor device, it is desirable to increase the first distance d1. Additionally, when an interface between the insulation materials (e.g., an interface between the first and second insulation interlayers) is positioned at the third portion, the insulation breakdown of the insulation material may easily occur at the interface between the insulation materials. Therefore, preferably, the interface between the insulation materials may not be positioned at the third portion.

An uppermost portion of the first portion of the first conductive pattern may have a width greater than a width of a lowermost portion of the first portion of the first conductive pattern. Therefore, if an upper portion of the first barrier metal pattern 106b is not recessed, the first distance d1 may be greatly decreased. In addition, if the upper portion of the first barrier metal pattern is not recessed, an interface between the upper surface of the first insulating interlayer and a lower surface of the second insulating interlayer may be positioned at the third portion to have a plane shape. In this case, the third portion may correspond to the interface between the upper surface of the first insulating interlayer and the lower surface of the second insulating interlayer. The interface between the first and second insulating interlayers may be may coincide with the third portion, and the first distance may be decreased. Therefore, insulation breakdown of insulation material positioned at the third position may easily occur.

However, in example embodiments, the uppermost surface of the first barrier metal pattern 106b may be lower than the upper surface of the first metal pattern 110a, and thus the first recess 144 may be included in the first contact plug 112a. In this case, the third portion may be positioned at a level lower than the uppermost surface of the first contact plug 112a. The third portion may not correspond to a portion between an uppermost portion of the first contact plug 112a and the first conductive pattern 134.

In addition, the first distance d1 in the case in which the upper portion of the first barrier metal pattern 106b is recessed may be greater than the first distance in the case in which the upper portion of the first barrier metal pattern 106b is not recessed.

The interface between the upper surface of the first insulating interlayer 102 and the lower surface of the second insulating interlayer 120 may not be positioned at the third portion. Only the first insulating interlayer 102 may be disposed at the third portion. Accordingly, the interface between the insulating interlayers positioned at the third portion may be more reliable.

The first distance d1 may be increased, and the interface between the first and second insulating interlayers 102 and 120 may not be positioned at the third portion. Accordingly, insulation breakdown of insulation material positioned at the third portion may be less likely.

A capping layer 140 may be disposed on the second metal pattern 132a, the second barrier metal pattern 130a, and the second insulating interlayer 120. The capping layer 140 may cover the upper surfaces of the second metal pattern 132a, the second barrier metal pattern 130a, and the second insulating interlayer 120. The capping layer 140 may include an insulation material, e.g., silicon nitride or silicon oxynitride.

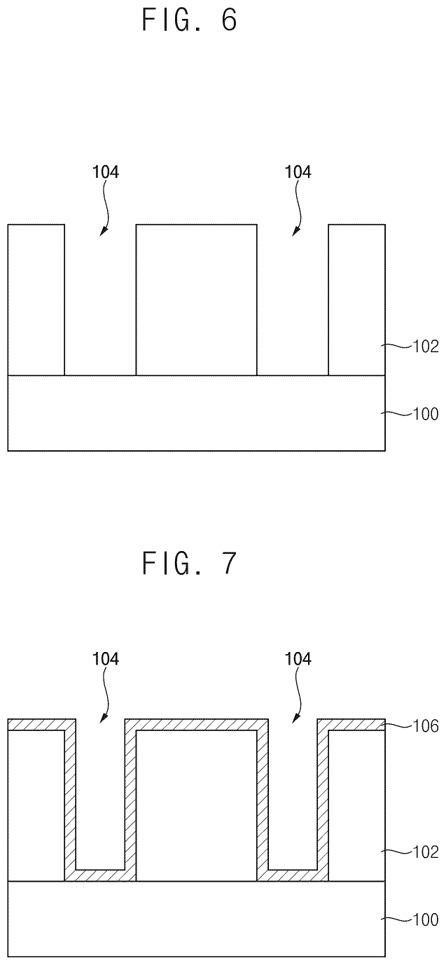

FIGS. 6 to 15 are cross-sectional views illustrating a method of manufacturing an interconnection structure of a semiconductor device according to example embodiments.

Referring to FIG. 6, a first insulating interlayer 102 may be formed on the substrate 100.

The substrate 100 may include silicon, germanium, silicon-germanium, or a group III-V compound such as GaP, GaAs, or GaSb. In some example embodiments, the substrate 100 may be a Silicon On Insulator (SOI) substrate or a Germanium On Insulator (GOI) substrate.

The first insulating interlayer 102 may include a silicon oxide-based material. For example, the first insulating interlayer 102 may include Tetra Ethyl Ortho Silicate (TEOS). In example embodiments, before forming the first insulating interlayer 102, a lower conductive structure may further be formed on an upper surface of the substrate 100.

An etch mask pattern may be formed on the first insulating interlayer 102, and the first insulating interlayer 102 may be etched using the etch mask pattern to form first contact holes 104. In example embodiments, the etch mask pattern may have a structure in which an amorphous carbon layer pattern and a silicon oxynitride layer pattern are stacked. The etch mask pattern may be formed by deposition processes of the amorphous carbon layer and the silicon oxynitride layer and photolithography processes of the amorphous carbon layer and the silicon oxynitride layer.

The etching process of the first insulating interlayer 102 may include a dry etching process.

Referring to FIG. 7, a first barrier metal layer 106 may be conformally formed on sidewalls and bottoms of the first contact holes 104 and on an upper surface of the first insulating interlayer 102.

In example embodiments, the first barrier metal layer 106 may be formed to have a uniform thickness on the sidewalls and on the bottoms of the first contact holes 104 and the upper surface of the first insulating interlayer 102.

The first barrier metal layer 106 may include, e.g., titanium, titanium nitride, tantalum, tantalum nitride, etc. The first barrier metal layer 106 may be formed by a chemical vapor deposition process or an atomic layer deposition process.

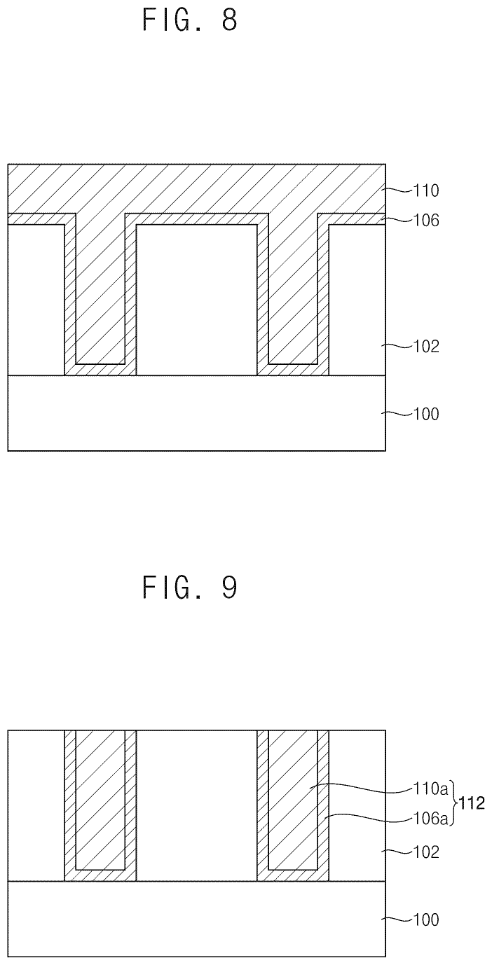

Referring to FIG. 8, the first metal layer 110 may be formed on the first barrier metal layer 106 to fill the first contact holes 104.

The first metal layer 110 may include, e.g., tungsten. In this case, the first metal layer 110 may be formed by a chemical vapor deposition process or an atomic layer deposition process using at least WF6 as a deposition source.

In some example embodiments, the first metal layer 110 may include aluminum, copper, ruthenium, cobalt, nickel, palladium, platinum, silver, gold, etc.

Referring to FIG. 9, the first barrier metal layer 106 and the first metal layer 110 may be planarized until the upper surface of the first insulating interlayer 102 is exposed to form a preliminary first contact plug 112 in each of the first contact holes 104. The preliminary first contact plug 112 may include a preliminary first barrier metal pattern 106a and a first metal pattern 110a. The planarization process may include, e.g., a chemical mechanical polishing process and/or an etch-back process.

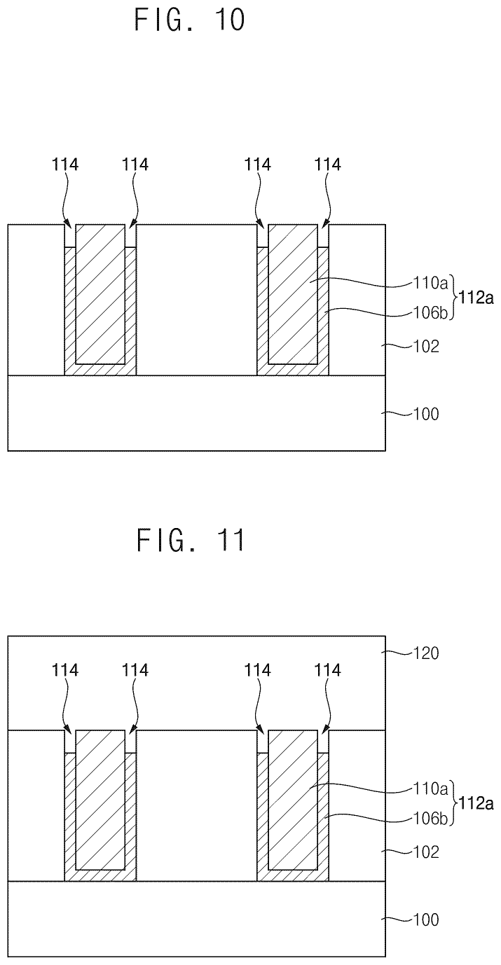

Referring to FIG. 10, an upper portion of the preliminary first barrier metal pattern 106a may be partially etched to form a first barrier metal pattern 106b. Accordingly, the first contact plug 112a including the first barrier metal pattern 106b and the first metal pattern 110a may be formed in each of the first contact holes 104.

An uppermost surface of the first barrier metal pattern 106b may be lower than an upper surface of the first metal pattern 110a. A first recess 114 may be formed between the first insulating interlayer 102 and the first metal pattern 110a above the uppermost surface of the first barrier metal pattern 106b. In the first contact plug 112a, an upper outer wall of the first metal pattern 110a may be exposed by the first recess 114.

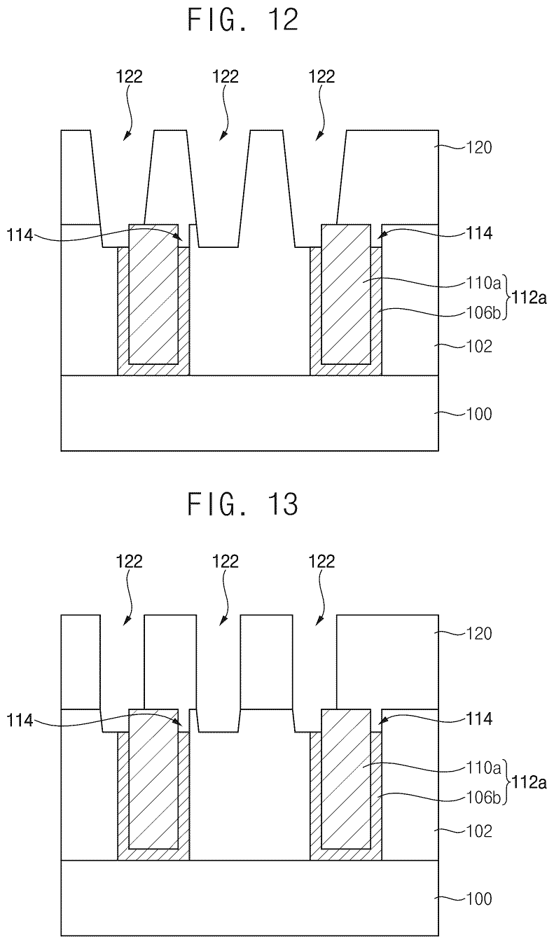

Referring to FIG. 11, a second insulating interlayer 120 may be formed on the first insulating interlayer 102 and the first contact plug 112a to fill the first recess 114. The second insulating interlayer 120 may cover the first insulating interlayer 102 and the first contact plug 112a. The same insulation material (e.g., the second insulating interlayer) may be formed in the first recess 114 and on the first insulating interlayer 102 and the first contact plug 112a.

In example embodiments, voids may not be present in the second insulating interlayer 120 formed in the first recess 114.

In some example embodiments, voids may be present in the second insulating interlayer 120 formed in the first recess 114. In this case, the interconnection structure shown in FIG. 4 may be formed by subsequent processes.

In some example embodiments, the second insulating interlayer 120 may not fill the first recess 114. The second insulating interlayer 120 may be formed on the first insulating interlayer 102 and the first contact plug 112a to cover an inlet of the first recess 114. Accordingly, the first recess 114 may be empty. In this case, the interconnection structure shown in FIG. 5 may be formed by subsequent processes.

Referring to FIGS. 12 and 13, portions of the second insulating interlayer 120 and the first insulating interlayer 102 may be etched to form openings 122. Processes for forming the openings 122 may include a photo process and an etching process. The etching process may include, e.g., a dry etching process.

The openings 122 may pass through the second insulating interlayer 120, and may extend into a portion under the upper surface of the first insulating interlayer 102 in the vertical direction. A first portion of a bottom of each of the openings 122 may expose an upper surface of the first contact plug 112a. A second portion of the bottom of the each of the openings 122 may expose the first insulating interlayer 102, and may be lower than the upper surface of the first insulating interlayer 102. The second portion of the bottom of each of the openings 122 may be at an inner portion of the first insulating interlayer 102.

In example embodiments, in a plan view, each of the openings 122 may have a line shape extending in one direction or a square shape.

In example embodiments, the upper surface of the first contact plug 112a exposed by each of the openings 122 may be hardly etched during the etching process. Accordingly, in each of the openings 122, the portion of the bottom exposing the first contact plug 112a may be higher than the other portion of the bottom exposing the first insulating interlayer 102.

In example embodiments, a lowermost surface of each of the openings 122 may be coplanar with the uppermost surface of the first barrier metal pattern 106b. In some example embodiments, the lowermost surface of each of the openings 122 may be lower than the uppermost surface of the first barrier metal pattern 106b.

In example embodiments, a lower width of the opening 122 may be less than a width of the first contact plug 112a. Accordingly, in the process for forming the openings 122, an entirety of the upper surface of the first contact plug 112a may not be exposed by each of the openings 122, but a portion of the upper surface of the first contact plug 112a may be exposed by each of the openings 122. Additionally, after forming the openings 122, at least a portion of the second insulating interlayer 120 filling the first recess 114 of the first contact plug 112a may remain without being removed.

Each of the openings 122 may have a sidewall slope such that a width at the bottom of the opening 122 is less than a width at an upper portion of the opening 122.

In example embodiments, a portion of the opening 122 positioned lower than the upper surface of the second insulating interlayer 120 may have a sidewall slope such that the width of the opening 122 gradually decreases toward the bottom thereof.

For example, as shown in FIG. 12, the opening 122 may have a sidewall slope such than the width gradually decreases from an upper portion to the bottom thereof. The sidewall slope may be constant. In this case, the interconnection structure shown in FIG. 1A or FIG. 1B may be formed by subsequent processes. For example, as shown in FIG. 13, a portion of the opening 122 positioned higher than the upper surface of the second insulating interlayer 120 has a vertical sidewall slope, and a portion of the opening 122 positioned lower than the upper surface of the second insulating interlayer 120 may have a sidewall slope such that the width of the opening 122 gradually decreases toward the bottom thereof. In this case, the interconnection structure shown in FIG. 1C may be formed by subsequent processes.

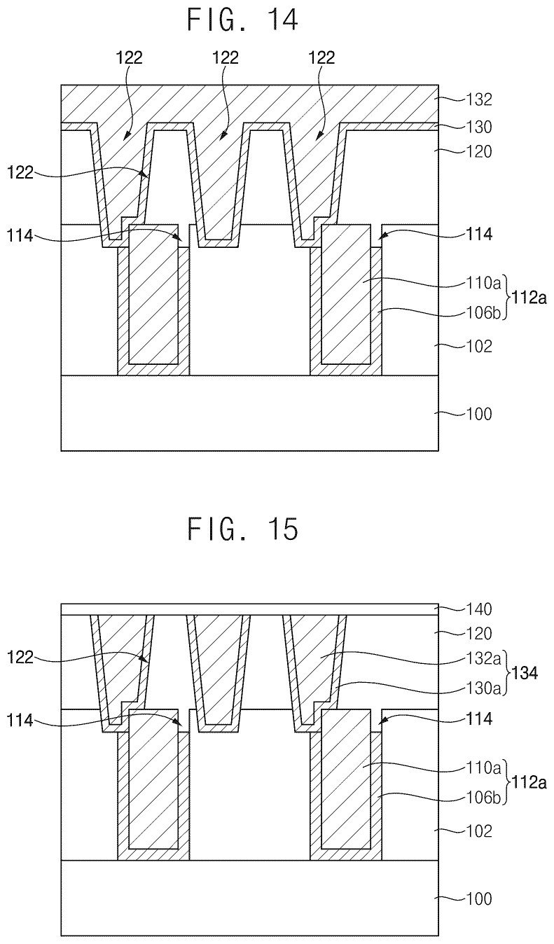

Referring to FIG. 14, a second barrier metal layer 130 may be conformally formed on sidewalls and bottoms of the openings 122 and on the upper surface of the second insulating interlayer 120. A second metal layer 132 may be formed on the second barrier metal layer 130 to fill the openings 122.

The second barrier metal layer 130 may include, e.g., titanium, titanium nitride, tantalum, tantalum nitride, etc. The second barrier metal layer 130 may be formed by a chemical vapor deposition process or an atomic layer deposition process.

In example embodiments, the second barrier metal layer 130 may be formed on the sidewalls and on the bottoms of the openings 122 and the upper surface of the second insulating interlayer 120 to have a uniform thickness. In some example embodiments, a thickness of the second barrier metal layer 130 formed on the sidewalls of the openings 122 may be less than a thickness on the bottoms of the openings 122 and on the upper surface of the second insulating interlayer 120.

In example embodiments, the second metal layer 132 may include a material having a resistance lower than a resistance of the first metal pattern 110a. The second metal layer 132 may include, e.g., copper. In some example embodiments, the second metal layer 132 may include, e.g., aluminum, ruthenium, cobalt, nickel, palladium, platinum, silver, or gold.

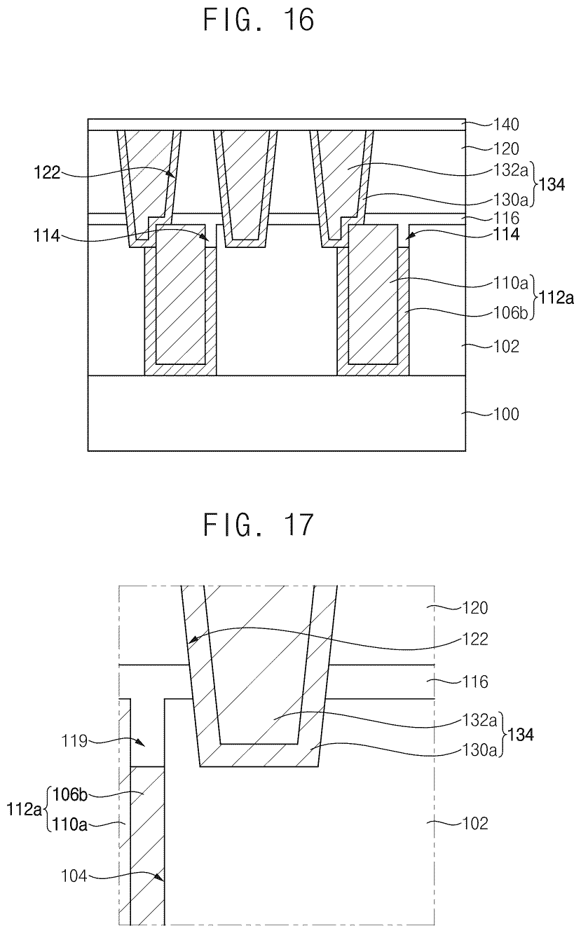

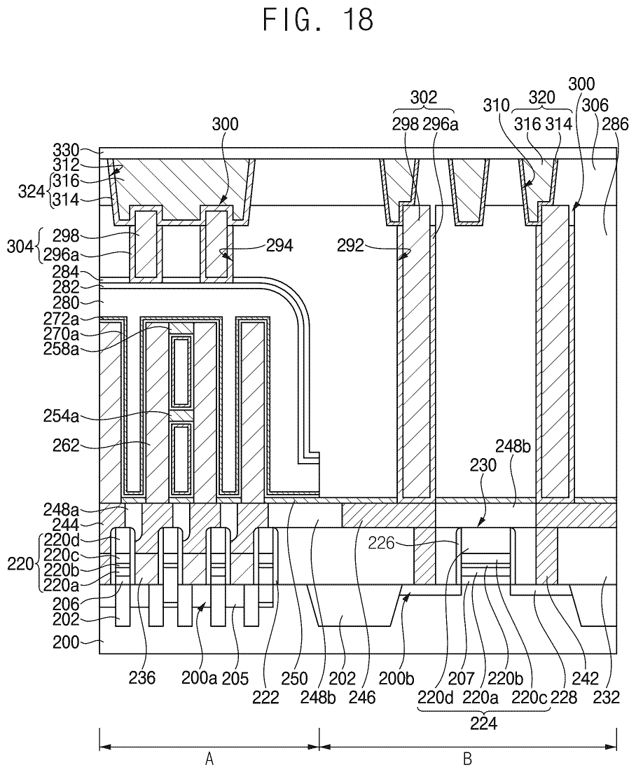

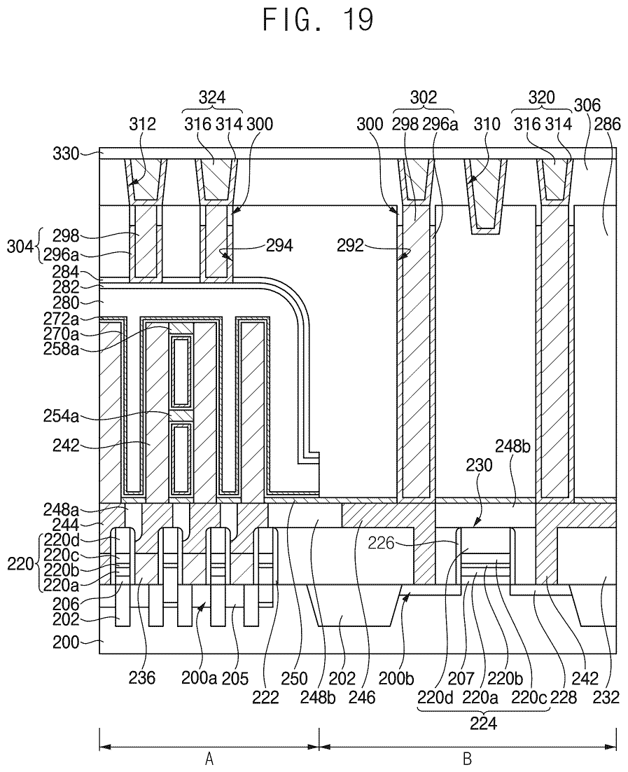

Referring to FIG. 15, the second metal layer 124 and the second barrier metal layer 130 may be planarized until the upper surface of the second insulating interlayer 120 is exposed to form a first conductive pattern 134 filling each of the openings 122. The first conductive pattern 134 may include a second barrier metal pattern 130a and a second metal pattern 132a. The planarization process may include, e.g., a chemical mechanical polishing process and/or an etch-back process.

Since the first conductive pattern 134 is formed in each of the openings 122, the first conductive pattern 134 may have a shape the same as a shape of an inner portion of each other the openings 122.

Thereafter, a capping layer 140 may be formed on the second metal pattern 132a, the second barrier metal pattern 130a, and the second insulating interlayer 120. The capping layer 140 may cover upper surfaces of the second metal pattern 132a, the second barrier metal pattern 130a, and the second insulating interlayer 120. The capping layer 140 may include an insulation material, e.g., silicon nitride or silicon oxynitride.

FIG. 16 is a cross-sectional view of an interconnection structure of a semiconductor device according to example embodiments. FIG. 17 is an enlarged cross-sectional view of a portion of FIG. 16.

The interconnection structure of the semiconductor device shown in FIG. 16 may be the same as the interconnection structure shown in FIG. 1A, except that an adhesive layer is further included.

Referring to FIGS. 16 and 17, an adhesive layer 116 may be on the first contact plug 112a and the adhesive layer 116 may further be on the first insulating interlayer 102 to fill the first recess 114. The adhesive layer 116 may cover upper surfaces of the first contact plug 112a and the first insulating interlayer 102. A second insulating interlayer 120 may be on the adhesive layer 116.

The adhesive layer 116 may be disposed between the first insulating interlayer 102 and the second insulating interlayer 120 and the adhesive layer 116 may be further disposed between the first contact plug 112a and the second insulating interlayer 120.

The adhesive layer 116 may have a thickness less than a thickness of the second insulating interlayer 120, and an upper surface of the adhesive layer 116 may be substantially flat. The adhesive layer 116 may include, e.g., a silicon oxide-based material. The adhesive layer 116 may be provided to improve adhesion between the first and second insulating interlayers 102 and 120.

In example embodiments, a void may not be present in the adhesive layer 116 formed in the first recess 114. In some example embodiments, a void may be present in the adhesive layer 116 formed in the first recess 114.

The interconnection structure shown in FIG. 16 may be formed by performing the same processes as processes described with reference to FIGS. 6 to 15, except that a process for forming the adhesive layer 116 may be further performed. First, the processes described with reference to FIGS. 6 to 10 may be performed. Thereafter, before forming the second insulating interlayer 120, the adhesive layer 116 may be formed on the first insulating interlayer 102 and the adhesive layer 116 may be further formed on the first contact plug 112a to fill the first recess 114. Thereafter, the process described with reference to FIGS. 11 to 15 may be performed on the adhesive layer to form the interconnection structure shown in FIG. 16.

FIG. 18 is a cross-sectional view of a semiconductor device according to example embodiments. FIG. 19 is a cross-sectional view of a semiconductor device according to some example embodiments.

The semiconductor device shown in FIGS. 18 and 19 may be a DRAM device.

Referring to FIG. 18, a semiconductor device may be on a substrate 200 including a cell region A and a peripheral circuit region B.

The substrate 200 may be a wafer substrate including silicon, germanium, silicon-germanium, or a group III-V compound such as GaP, GaAs, GaSb, etc. In some example embodiments, the substrate 200 may be a Silicon On Insulator (SOI) wafer or a Germanium On Insulator (GOI) wafer.

Isolation layers 202 may be at the substrate 200. The substrate 200 between the isolation layers 202 may be configured as an active region. A first active pattern 200a may be in the cell region A, and a second active pattern 200b may be in the peripheral circuit region B.

The cell region A of the substrate 200 may include a gate trench extending in a first direction parallel to an upper surface of the substrate 200. A first gate structure may be in the gate trench. In example embodiments, the first gate structure may include a gate insulation layer, a gate electrode, and a capping pattern.

First impurity regions 205 configured as source/drain regions may be at upper portions of the first active patterns 200a between the first gate structures. The first gate structure and first impurity regions 205 may be configured as a selection transistor. The selection transistor may be a recess channel transistor including the first gate structure buried in the substrate 200.

An insulation layer pattern 206 may be on the first active pattern 200a, the isolation layer 202, and the first gate structure in the cell region A.

A bit line structure 220 may be on the insulation layer pattern 206 and the substrate 200. The bit line structure 220 may be on the cell region A of the substrate 200. The bit line structure 220 may contact one of the first impurity regions 205.

The bit line structure 220 may include a first conductive pattern 220a, a first barrier metal pattern 220b, a first metal pattern 220c, and a hard mask pattern 220d. For example, the first conductive pattern 220a may include polysilicon doped with impurities. The bit line structure 220 may extend in a second direction perpendicular to the first direction, and a plurality of bit line structures may be spaced apart from each other in the first direction. In example embodiments, a first spacer 222 may be on a sidewall of the bit line structure 220.

Peripheral circuit patterns may be on the peripheral circuit region B of the substrate 200. The peripheral circuit patterns may include, e.g., a peripheral circuit transistor 230, lower wiring, etc. The peripheral circuit transistor 230 may include a second gate structure 224 and second impurity regions 228 configured as source/drain regions. The second impurity regions 228 may be at upper portions of the second active patterns 200b adjacent to both sidewalls of the second gate structure 224. The peripheral circuit transistor 230 may be configured as a sense amplifier, page buffer, command circuit, etc.

The second gate structure 224 may include a gate insulation layer pattern 207, the first conductive pattern 220a, the first barrier metal pattern 220b, the first metal pattern 220c, and the hard mask pattern 220d. In example embodiments, an upper surface of the second gate structure 224 may be substantially coplanar with an upper surface of the bit line structure 220 in the cell region A. Each of the second gate structures 224 and the bit line structures 220 may include the first conductive pattern 220a, the first barrier metal pattern 220b, the first metal pattern 220c, and the hard mask pattern 220d. Therefore, the second gate structures 224 and the bit line structures 220 may have the same stacked structure.

In example embodiments, a second spacer 226 may be on a sidewall of the second gate structure 224.

A first insulating interlayer 232 may occupy a space between the bit line structures 220, and may cover the sidewall of the second gate structure 224 on the peripheral circuit transistor 230. In example embodiments, an upper surface of the first insulating interlayer 232 may be coplanar with upper surfaces of the bit line structure 220 and the second gate structure 224.

A contact structure may pass through the first insulating interlayer 232 and the insulation layer pattern 206 on the cell region A, and the contact structure may contact a portion of the first impurity region 205. The contact structure may have a structure in which a first lower contact plug 236 and a landing pad 244 are stacked.

The first lower contact plug 236 may be disposed between the bit line structures 220, and a plurality of first lower contact plugs 236 may be spaced apart from each other. An upper surface of the first lower contact plug 236 may be lower than the upper surface of the bit line structure 220. In example embodiments, the first lower contact plug 236 may include polysilicon.

The landing pad 244 may be on the first lower contact plug 236. An upper surface of the landing pad 244 may be higher than the upper surface of the bit line structure 220. A first upper insulating pattern 248a may be disposed between the landing pads 244 in the horizontal direction. In example embodiments, an upper portion of the hard mask pattern 220d in the bit line structure 220 may be partially etched through a pattering process, so that an upper portion of the hard mask pattern 220d contacting the first upper insulating pattern 248 may have a recessed shape. In example embodiments, the landing pad 244 may include tungsten. In example embodiments, a barrier metal pattern may be further included at an interface between the landing pad 244 and the first lower contact plug 236.

A second lower contact plug 242 may pass through the first insulating interlayer 232 on the peripheral circuit region B, and the second lower contact plug 242 may be connected to the second impurity regions 228 or the first metal pattern 220c of the second gate structure 224.

A second conductive pattern 246 may be on the first insulating interlayer 232 on the peripheral circuit region B. The second conductive patterns 246 may be wiring lines for electrically connecting the peripheral circuits. The second conductive patterns 246 may include the same material as the landing pad 244 on the cell region A.

A second upper insulating pattern 248b may be between the second conductive patterns 246. Upper surfaces of the second conductive patterns 246 and the second upper insulating pattern 248b may be coplanar with upper surfaces of the landing pad 244 and the first upper insulating pattern 248a.

A first etch stop layer 250 may be on the upper surfaces of the landing pad 244, the second conductive patterns 246, and the first and second upper insulating patterns 248a and 248b. The first etch stop layer 250 may include, e.g., silicon nitride.

A cell capacitor may pass through the first etch stop layer 250, and may contact the landing pad 244. The cell capacitor may include a plurality of lower electrodes 262, a dielectric layer pattern 270a, and an upper electrode 272a. In addition, the cell capacitor may further include a lower support layer pattern 254a and an upper support layer pattern 258a for supporting the lower electrodes 262.

The lower electrodes 262 may pass through the first etch stop layer 250, and the lower electrodes 262 may be on the upper surface of each of the landing pads 244, respectively. In example embodiments, the lower electrodes 262 may have a pillar shape. In some example embodiments, the lower electrodes 262 may have a cylindrical shape.

In example embodiments, the lower electrodes 262 may include a metal, e.g., Ti, W, Ni, or Co, or a metal nitride, e.g., TiN, TiSiN, TiAlN, TaN, TaSiN, or WN. For example, the lower electrodes 262 may include TiN.

Each of the lower support layer pattern 254a and the upper support layer pattern 258a may be disposed between the lower electrodes 262. Each of the lower support layer pattern 254a and the upper support layer pattern 258a may be connected to sidewalls of the lower electrodes 262, so that each of the lower support layer pattern 254a and the upper support layer pattern 258a may support the sidewalls of the lower electrodes 262. The lower support layer pattern 254a and the upper support layer pattern 258a may include an insulation material, e.g., silicon nitride or silicon oxynitride.

In some example embodiments, at least one of the upper support layer pattern 258a and the lower support layer pattern 254a may not be included. In some example embodiments, two or more first lower support layer patterns may be below the upper support layer pattern 258a.

The dielectric layer pattern 270a may conform to surfaces of the lower electrode 262, the lower support layer pattern 254a, the upper support layer pattern 258a, and the first etch stop layer 250. The dielectric layer pattern 270a may include a high-k dielectric layer. In example embodiments, the high-k dielectric layer may include a metal layer, e.g., a hafnium oxide layer (HfO2), a zirconium oxide layer (ZrO2), an aluminum oxide layer (Al2O3), or a lanthanum oxide layer (La2O5).

The upper electrode 272a may be on the dielectric layer pattern 270a. In example embodiments, the upper electrode 272a may include metal nitride. The metal nitride may include, e.g., titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), tungsten nitride (WN), or the like.

In example embodiments, the upper electrode 272a may conform to the dielectric layer pattern 270a, and may not completely occupy a space between the lower electrodes 262.

The dielectric layer pattern 270a and the upper electrode 272a may be only on the cell region A of the substrate 200. The dielectric layer pattern 270a and the upper electrode 272a may not be on the peripheral circuit region B of the substrate 200. Accordingly, the dielectric layer pattern 270a and the upper electrode 272a B may be stacked on the upper surface of the first etch stop layer 250 at an edge portion of the cell region A adjacent to the peripheral circuit region B.

A first plate pattern 280 may be on the surface of the upper electrode 272a. In example embodiments, the first plate pattern 280 may be only on the cell region A. The first plate pattern 280 may include, e.g., silicon germanium.

In example embodiments, the first plate pattern 280 may occupy a space between the upper electrodes 272a, and the first plate pattern 280 may cover an uppermost surface of the upper electrode 272a. Additionally, the first plate pattern 280 may be on the edge of the cell region A and on a sidewall of a last cell capacitor on the edge of the cell region A adjacent to the peripheral circuit region B. The first plate pattern 280 may not be on the peripheral circuit region B.

In example embodiments, the first plate pattern 280 may include a first portion, a second portion, and a third portion. The first portion may be positioned on the upper electrode 272a on the cell region A, and an upper surface of the first portion may be substantially flat. The second portion may cover the last cell capacitor on the cell region A adjacent to the peripheral circuit region B, and may have a vertical surface perpendicular to the surface of the substrate 200. The third portion may be connected to the second portion, and an upper surface of the third portion may be substantially flat. The third portion may be positioned on the edge of the cell region A adjacent to the peripheral circuit region.

An upper metal pattern 282 and a second etch stop pattern 284 may be stacked on the first plate pattern 280.

A second insulating interlayer 286 may be on the second etch stop pattern 284 and the first etch stop layer 250. An upper surface of the second insulating interlayer 286 may be substantially flat. The upper surface of the second insulating interlayer 286 may be higher than an upper surface of the second etch stop pattern 284.

A first contact plug 302 may pass through the second insulating interlayer 286 and the first etch stop layer 250 on the peripheral region, and may contact each of the second conductive patterns 246. The first contact plug 302 may be disposed in the first contact hole 292.

A second contact plug 304 may pass through the second insulating interlayer 286 and the second etch stop pattern 284 on the cell region, and may contact the upper metal pattern 282. The second contact plug 304 may be disposed in the second contact hole 294 passing through the second insulating interlayer 286 and the second etch stop pattern 284 and exposing the upper metal pattern 282.

The second contact plug 304 may be disposed over the cell capacitor. Accordingly, a bottom of the second contact plug 304 may be higher than a bottom of the first contact plug 302. The upper surface of the second contact plug 304 and the upper surface of the first contact plug 302 may be coplanar with each other. A height in the vertical direction of the first contact plug 302 may be greater than a height in the vertical direction of the second contact plug 304.

Each of the first and second contact plugs 302 and 304 may include a second barrier metal pattern 296a and a second metal pattern 298. The second barrier metal pattern 296a may cover a portion of a sidewall of the second metal pattern 298 and a bottom of the second metal pattern 298.

An upper surface of the second metal pattern 298 may be substantially coplanar with the upper surface of the second insulating interlayer 286. Additionally, an uppermost surface of the second barrier metal pattern 296a may be lower than the upper surface of the second metal pattern 298. The second barrier metal pattern 296a may not be on an upper sidewall of the second metal pattern 298.

A first recess 300 may be disposed between the upper sidewall of the second metal pattern 298 and the second insulating interlayer 286, and the first recess 300 may have a shape surrounding the upper sidewall of the second metal pattern 298. The first recess 300 may be disposed above the uppermost surface of the second barrier metal pattern 296a.

A third insulating interlayer 306 may be on the first contact plug 302, the second contact plug 304, and the second insulating interlayer 286.

In example embodiments, the third insulating interlayer 306 may occupy the first recess 300. A silicon oxide-based material may occupy the first recess 300. The first recess 300 may not be occupied with nitride material, such as silicon nitride.

In example embodiments, the third insulating interlayer 306 in the first recess 300 may not include voids. In some example embodiments, the third insulating interlayer 306 in the first recess 300 may include voids. In some example embodiments, the third insulating interlayer 306 may not occupy the first recess 300.

First and second openings 310 and 312 may pass through the third insulating interlayer 306, and may extend into a portion under the upper surface of the second insulating interlayer 120 in the vertical direction. The first openings 310 may be disposed on the peripheral circuit region B, and the first contact plug 302 may be exposed by at least a portion of the first openings 310. The second opening 312 are disposed on the cell region A, and the second contact plug 304 may be exposed by at least a portion of the second opening 312.

Each of the first and second openings 310 and 312 may have a sidewall slope such that a lower width of each of the first and second openings 310 and 312 may be less than an upper width of each of the first and second openings 310 and 312. A first conductive pattern structure 320 may be in each of the first openings 310, and a second conductive pattern structure 324 may be in the second opening 312.

A first bottom surface of the first conductive pattern structure 320 may contact an upper surface of the first contact plug 302. A second bottom surface of the first conductive pattern structure 320 may contact the second insulating interlayer 286. The third bottom surface of the second conductive pattern structure 324 may contact an upper surface of the second contact plug 304. The fourth bottom surface of the second conductive pattern structure 324 may contact the second insulating interlayer 286.

The first bottom surface of the first conductive pattern structure 320 may be positioned higher than the second bottom surface of the first conductive pattern structure 320. The third bottom surface of the second conductive pattern structure 324 may be positioned higher than the fourth bottom surface of the second conductive pattern structure 324. The second and fourth bottom surfaces may be in the second insulating interlayer 286. In example embodiments, the second and fourth bottom surfaces may be coplanar with or lower than a bottom of the first recess 300.

Each of the first and second conductive pattern structures 320 and 324 may include a third barrier metal pattern 314 and a third metal pattern 316. The third barrier metal pattern 314 may cover a sidewall and a bottom of the third metal pattern 316.

The third metal pattern 316 may be on the third barrier metal pattern 314 to occupy the first and second openings 310 and 312. Upper surfaces of the third metal pattern 316 and the third barrier metal pattern 314 may be substantially coplanar with an upper surface of the third insulating interlayer 306.

In example embodiments, a width of an uppermost portion of each of the first and second conductive pattern structures 320 and 324 may be less than a width of a lowermost portion of the first and second conductive pattern structures 320 and 324. In example embodiments, at least a lower portion of each of the first and second conductive pattern structures 320 and 324 may have a sidewall slope such that the width of the lower portion of each of the first and second conductive pattern structures 320 and 324 gradually decreases downward.

A portion of the first conductive pattern structure 320 lower than the upper surface of the second insulating interlayer 286 is referred to in the following disclosure as a fourth portion. In the claims, the recitation of a “fourth portion” without more is not intended to incorporate this definition therein. The fourth portion of the first conductive pattern structure 320 may be adjacent to the first contact plug 302 to be spaced apart from the first contact plug 302 in the horizontal direction.

In a cross-sectional view, the upper sidewall of the first contact plug 302 and the fourth portion of the first conductive pattern structure 320 may face toward each other in the horizontal direction.

A distance in the horizontal direction between an uppermost sidewall of the second metal pattern 298 of the first contact plug 302 and the first conductive pattern structure 320 may be greater than a distance in the horizontal direction between an uppermost sidewall of the second barrier metal pattern 296a of the first contact plug 302 and the first conductive pattern structure 320.

In example embodiments, an upper portion of the fourth portion of the first conductive pattern structure 320 may face the sidewall of the second metal pattern 298, and a lower portion of the fourth portion of the first conductive pattern structure 320 may face the sidewall of the second barrier metal pattern 296a. In some example embodiments, the fourth portion of the second conductive pattern structure 324 may face only the sidewall of the second metal pattern 298.

The distance in the horizontal direction between the uppermost sidewall of the second barrier metal pattern 296a of the first contact plug 302 and the first conductive pattern structure 320 is referred to in the following disclosure as a first distance. In the claims, the recitation of a “first distance” without more is not intended to incorporate this definition therein. Since the uppermost portion of the second barrier metal pattern 296a has a recessed shape, the first distance may be greater than a first distance when an uppermost portion of a second barrier metal pattern is not recessed.

A region having the first distance may be a weak region where insulation breakdown of insulation material between the first contact plug 302 and the first conductive pattern structure 320 easily occurs, and thus reliability of the semiconductor device may be compromised. However, since an interface between the insulation materials is not positioned at the region having the first distance, reliability may be improved.

The second conductive pattern structure 324 may extend in one direction (e.g., longitudinal direction). In example embodiments, as shown in FIG. 18, two or more second contact plugs 304 arranged in a width direction perpendicular to the longitudinal direction may contact the bottom of the same second conductive pattern structure 324. In some example embodiments, as shown in FIG. 19, only one second contact plug 304 in the width direction may contact the bottom of the second conductive pattern structure 324.

A capping layer 330 may be on the first conductive pattern structure 320, the second conductive pattern structure 324, and the third insulating interlayer 306. The capping layer 330 may cover the first conductive pattern structure 320, the second conductive pattern structure 324, and the third insulating interlayer 306. The capping layer 330 may include an insulation material, e.g., silicon nitride or silicon oxynitride.

As described above, a portion of the first conductive pattern structure formed on the peripheral circuit region in the DRAM device may face the upper portion of the first contact plug disposed below the first conductive pattern structure in the horizontal direction. Since the upper portion of the barrier metal pattern included in the first conductive pattern structure has the recessed shape, a minimum distance between the first conductive pattern structure and the first contact plug may be increased. Additionally, the interface of the insulation material may not be positioned at a region having the minimum distance. Therefore, the DRAM device may have high reliability.

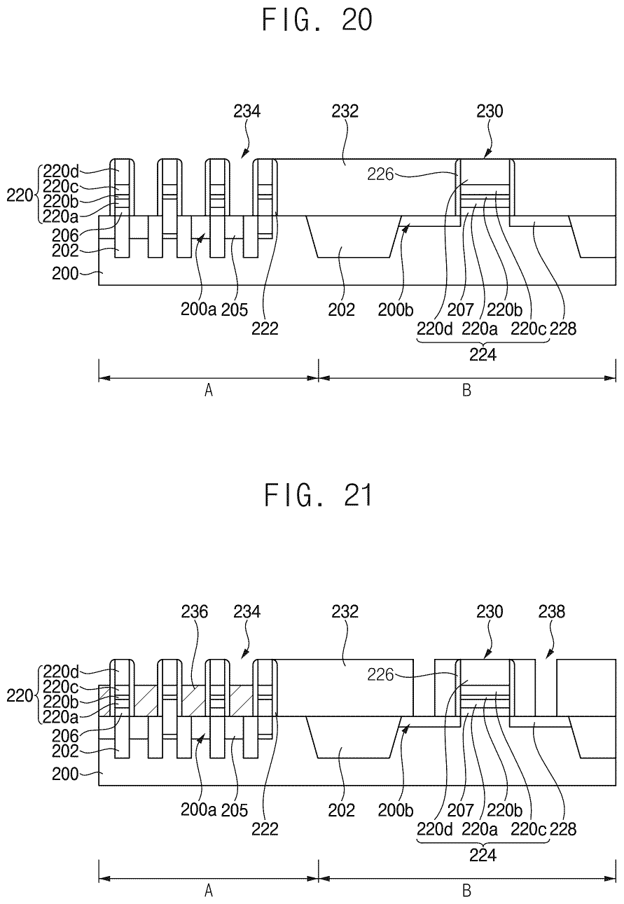

FIGS. 20 to 34 are cross-sectional views illustrating a method of manufacturing a semiconductor device according to example embodiments.

Referring to FIG. 20, an isolation layer 202 for defining an active region may be formed on the substrate 200 including a cell region A and a peripheral circuit region B. Accordingly, a first active pattern 200a may be formed on the cell region A, and the second active pattern 200b may be formed on the peripheral circuit region B.

Select transistors may be formed on the cell region A of the substrate 200. Each of the selection transistors may include a first gate structure and first impurity regions 205. In example embodiments, a portion of the substrate 200 may be etched to form a gate trench, and the first gate structure may be formed in the gate trench. For example, the first gate structure may include a gate insulation layer, a gate electrode, and a capping pattern sequentially stacked.

An insulation layer pattern 206 may be formed on the cell region A of the substrate 200. A recess may be formed on the first active pattern 200a between the insulation layer patterns 206. An upper surface of the first impurity region 205 may be exposed by a bottom of the recess. Additionally, a gate insulation layer may be formed on the peripheral circuit region B of the substrate 200.

Bit line structures 220 may be formed on the insulation layer pattern 206 and the recess. The bit line structure 220 may include a first conductive pattern 220a, a first barrier metal pattern 220b, a first metal pattern 220c, and a hard mask pattern 220d. In example embodiments, a first spacer 222 may be formed on a sidewall of the bit line structure 220.

When the bit line structure 220 is formed on the cell region A, a second gate structure 224 may be formed on the peripheral circuit region B of the substrate 200 together. The second gate structure 224 may include a gate insulation layer pattern 207, a first conductive pattern 220a, a first barrier metal pattern 220b, a first metal pattern 220c, and a hard mask pattern 220d sequentially stacked. In example embodiments, a second spacer 226 may be formed on a sidewall of the second gate structure 224. After forming the second gate structure 224, second impurity regions 228 configured as source/drain regions may be formed at an upper portion of the second active pattern 200b adjacent to both sidewalls of the second gate structure 224.

Accordingly, a peripheral circuit transistor 230 including a second gate structure 224 and second impurity regions 228 may be formed on the peripheral circuit region B of the substrate 200. The peripheral circuit transistor 230 may form a peripheral circuit.

A first insulating interlayer 232 may be formed on the substrate 200 to cover the bit line structures 220 and the peripheral circuit transistor 230. Thereafter, an upper surface of the first insulating interlayer 232 may be planarized. In example embodiments, the first insulating interlayer 232 may be planarized until upper surfaces of the bit line structure 220 and the second gate structure 224 are exposed.

A portion of the first insulating interlayer 232 between the bit line structures 220 may be etched to form a first lower contact hole 234 exposing a portion of the first impurity region 205 of the substrate 200.

Referring to FIG. 21, a first conductive layer may be formed on the first insulating interlayer 232 to fill the first lower contact hole 234. Thereafter, the first conductive layer may be partially etched by an etch-back process to form a first lower contact plug 236 filling a lower portion of the first lower contact hole 234. In the etch-back process, all of the first conductive layer formed on the first insulating interlayer 232 may be removed. In example embodiments, the first lower contact plug 236 may include polysilicon.

Thereafter, a portion of the first insulating interlayer 232 on the peripheral circuit region B may be etched to form a second lower contact hole 238 exposing the second impurity region 228 in the second active pattern 200b.

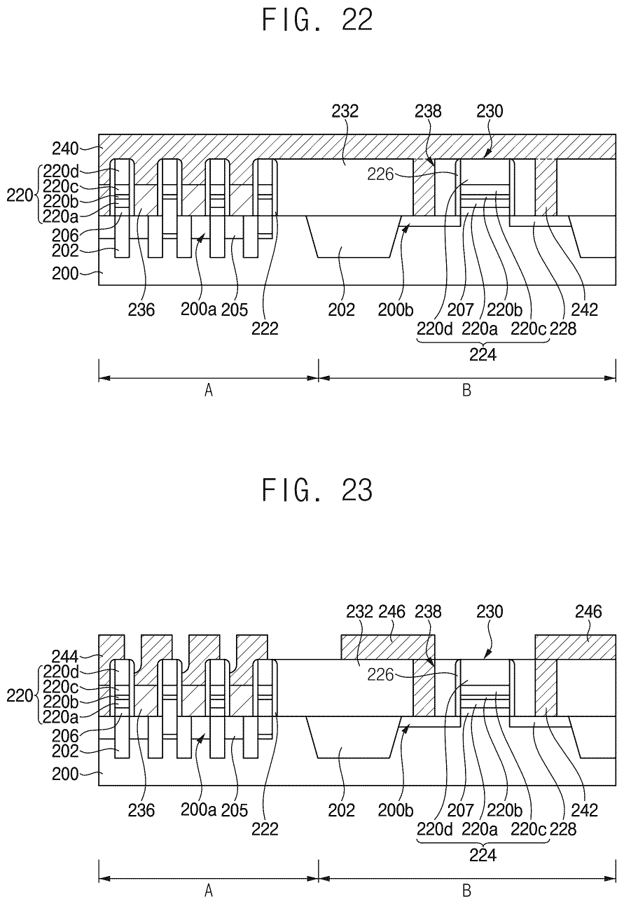

Referring to FIG. 22, a second conductive layer 240 may be formed to cover the bit line structure 220, the first lower contact plug 236, and the first insulating interlayer 232. The second conductive layer may fill the first lower contact hole 234 and the second lower contact hole 238. In example embodiments, the second conductive layer 240 may include tungsten. In some example embodiments, before forming the second conductive layer 240, a process for forming a barrier metal layer may be further performed.

In example embodiments, before forming the second conductive layer 240, a process for forming a metal silicide pattern on the first lower contact plug 236 may be further performed. In this case, the metal silicide pattern may also be formed on the surface of the substrate 200 exposed by a bottom of the second lower contact hole 238 on the peripheral circuit region B. By the above process, a second lower contact plug 242 may be formed in the second lower contact hole 238 on the peripheral circuit region B.

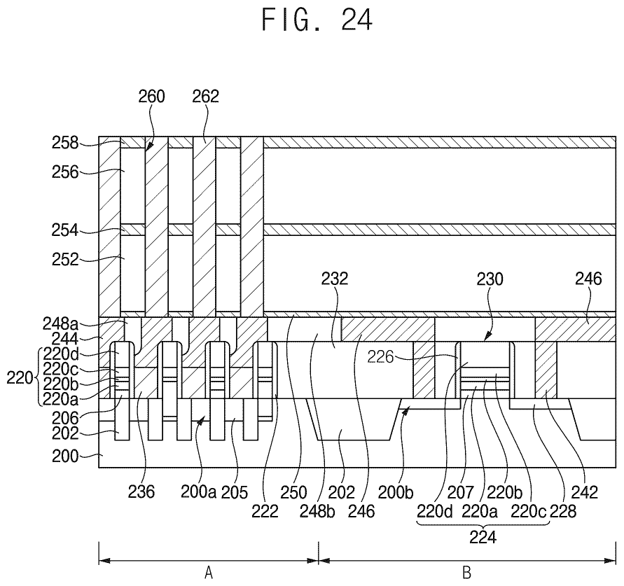

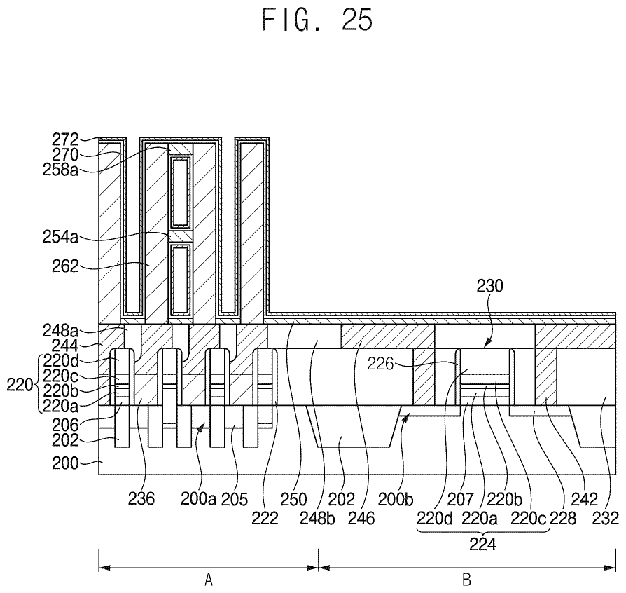

Referring to FIG. 23, the second conductive layer 240 on the cell region A may be patterned to form a landing pad 244 contacting an upper surface of the first lower contact plug 236. The second conductive layer 240 on the peripheral circuit region B may be patterned to form second conductive patterns 246.

Patterning process for forming the landing pad 244 on the cell region A and the second conductive patterns 246 on the peripheral circuit region B may be performed by different photolithography processes or the same single photo lithography process.

In the patterning process, an upper portion of the hard mask pattern 220d included in the bit line structure 220 may be partially etched, so that the upper portion of the bit line structure 220 may have a recessed shape.

Referring to FIG. 24, an upper insulation layer may be formed on the landing pad 244, the second conductive patterns 246, and the first insulating interlayer 232. The upper insulation layer may be planarized until upper surfaces of the landing pad 244 and the second conductive patterns 246 are exposed. The planarization process may include, e.g., a chemical mechanical polishing process.

Accordingly, a first upper insulating pattern 248a may be formed in a gap between the landing pads 244, and a second upper insulating pattern 248b may be formed in a gap between the second conductive patterns 246. Upper surfaces of the landing pad 244, the second conductive pattern 246, and the first and second upper insulating patterns 248a and 248b may be substantially coplanar with each other. Additionally, upper surfaces of the landing pad 244, the second conductive pattern 246, and the first and second upper insulating patterns 248a and 148b may be substantially flat.

A first etch stop layer 250 may be formed on the landing pad 244, the second conductive pattern 246, and the first and second upper insulating patterns 248a and 248b. The first etch stop layer 250 may include, e.g., silicon nitride, silicon oxynitride, etc.

A first mold layer 252, a lower support layer 254, a second mold layer 256, and an upper support layer 258 may be sequentially deposited on the first etch stop layer 250.

The first and second mold layers 252 and 256 may include a material having an etch selectivity with respect to the lower support layer 254 and the upper support layer 258. The first mold layer 252 and the second mold layer 256 may include, e.g., silicon oxide, and the lower support layer 254 and the upper support layer 258 may include, e.g., silicon nitride.

In this example embodiment, two support layers may be included in the semiconductor device, but may not be limited thereto. In some example embodiments, a single support layer or three or more support layers may be included in the semiconductor device, depending on a structure of a cell capacitor. In some example embodiments, the support layer may not be formed, and thus one mold layer may be included in the semiconductor.

An etch mask may be formed on the upper support layer 258. The upper support layer 258, the second mold layer 256, the lower support layer 254, and the first mold layer 252 and the first etch stop layer 250 may be etched using the etch mask to form first holes. The etching process may include an anisotropic etching process. By the above process, first holes 260 may expose the upper surface of the landing pad 244 on the cell region A of the substrate 200.

Thereafter, a lower electrode layer may be formed to fill the first holes 260. The lower electrode layer may be planarized until an upper surface of the upper support layer 258 is exposed to form lower electrodes 262 filling the first holes 260. In this case, each of the lower electrodes 262 may have a pillar shape. The lower electrode 262 may include a metal, e.g., Ti, W, Ni, or Co, or a metal nitride such as TiN, TiSiN, TiAlN, TaN, TaSiN, or WN.

Referring to FIG. 25, a first mask pattern may be formed on the upper support layer 258 and the lower electrode 262. The first mask pattern may include amorphous carbon or polysilicon. The first mask pattern may include holes.

The upper support layer 258 may be anisotropically etched using the first mask pattern to form second holes exposing the upper portion of the second mold layer 256. Accordingly, an upper support layer pattern 258a may be formed on the cell region A of the substrate 200. Thereafter, the second mold layer 256 may be wet etched by supplying etchant through the second holes. Accordingly, the lower support layer 254 may be exposed. Additionally, upper sidewalls of the lower electrodes 262 may be exposed.

A portion of the lower support layer 254 may be etched to form third holes exposing an upper portion of the first mold layer 252. Accordingly, the lower support layer pattern 254a may be formed. The first mold layer 252 may be wet etched by supplying etchant through the third holes.

The upper support layer pattern 258a and the lower support layer pattern 254a may be connected to each other while contacting a portion of an outer wall of the lower electrode 262. Accordingly, sidewalls of the lower electrode 262 may be supported by the upper support layer pattern 258a and the lower support layer pattern 254a, so that a leaning of the lower electrode 262 may be prevented. Additionally, the surface of the lower electrode 262 may be exposed.

Thereafter, a dielectric layer 270 may be conformally formed along the surfaces of the lower electrode 262, the lower and upper support layer patterns 254a and 258a, and the first etch stop layer 250. An upper electrode layer 272 including metal may be formed on the dielectric layer 270.

The dielectric layer 270 may include a high dielectric layer. In example embodiments, the high-k dielectric layer may include a hafnium oxide layer (HfO2), a zirconium oxide layer (ZrO2), an aluminum oxide layer (Al2O3), or a lanthanum oxide layer (La2O5).

In example embodiments, the upper electrode layer 272 may include a metal nitride.

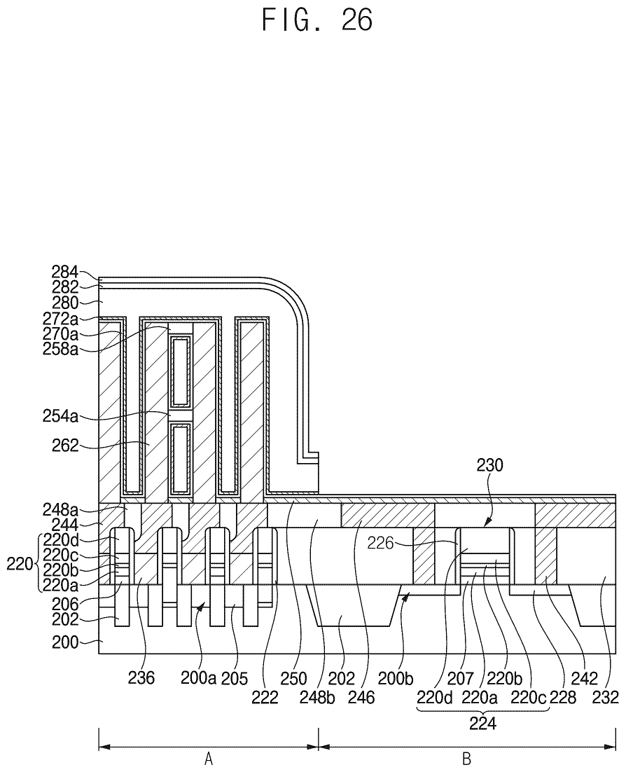

Referring to FIG. 26, a first plate layer may be formed on the upper electrode layer 272. The first plate layer may include, e.g., a silicon germanium layer. The silicon germanium layer may be doped with, e.g., P-type impurities or N-type impurities.

In example embodiments, the silicon germanium layer may be formed by an atomic layer deposition process or a chemical vapor deposition process using a silicon source gas, a germanium source gas, and a dopant gas as deposition gases.

The silicon source gas may include, e.g., silane (SiH4) or dichloro silane (SiH2Cl2). The germanium source gas may include, e.g., germanium (GeH4) or germanium tetrachloride (GeCl4). The dopant gas may include, e.g., borane (BH3), boron chloride (BCl3), phosphine (PH3), phosphorus chloride (PCl3), etc. Thereafter, the first plate layer may be crystallized by a heat treatment process.

Since the upper electrode layer 272 includes metal, it is not easy to increase a thickness of the upper electrode layer 272. Therefore, if the upper electrode is formed only using the upper electrode layer 272, a second contact plug subsequently formed may unintentionally pass through the upper electrode and extend into the lower electrode 262. Therefore, the first plate layer may serve as a buffer layer for decreasing the likelihood of such a defect in subsequent processes.

The first plate layer may be conformally formed on the upper electrode layer 272 on the cell region A and the peripheral circuit region B to fill a gap between the upper electrode layers 272.

An upper metal layer and a second etch stop layer may be formed on the first plate layer. The upper metal layer may include, e.g., tungsten. The second etch stop layer may include, e.g., silicon nitride or silicon oxynitride.

Thereafter, the second etch stop layer, the upper metal layer, the first plate layer, the upper electrode layer, and the dielectric layer on the peripheral circuit region B may be etched to form a dielectric layer pattern 270a, an upper electrode 272a, a first plate pattern 280, an upper metal pattern 282, and a second etch stop pattern 284. A stacked structure of the dielectric layer pattern 270a, the upper electrode 272a, the first plate pattern 280, the upper metal pattern 282, and the second etch stop pattern 284 may be formed only on the cell region A.

The first plate pattern 280 may have a first portion having an upper surface higher than the upper surface of the lower electrode 262 on the cell region A, a second portion covering a last cell capacitor in the cell region A adjacent to the peripheral circuit region B, and a third portion connected to the second portion and disposed at the edge of the cell region. The second portion of the first plate pattern 280 may have a vertical surface perpendicular to the surface of the substrate 200.

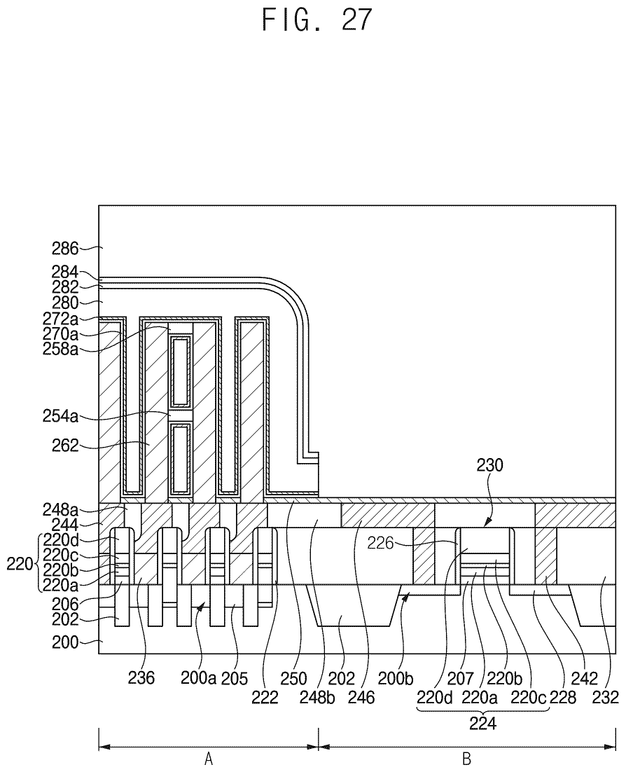

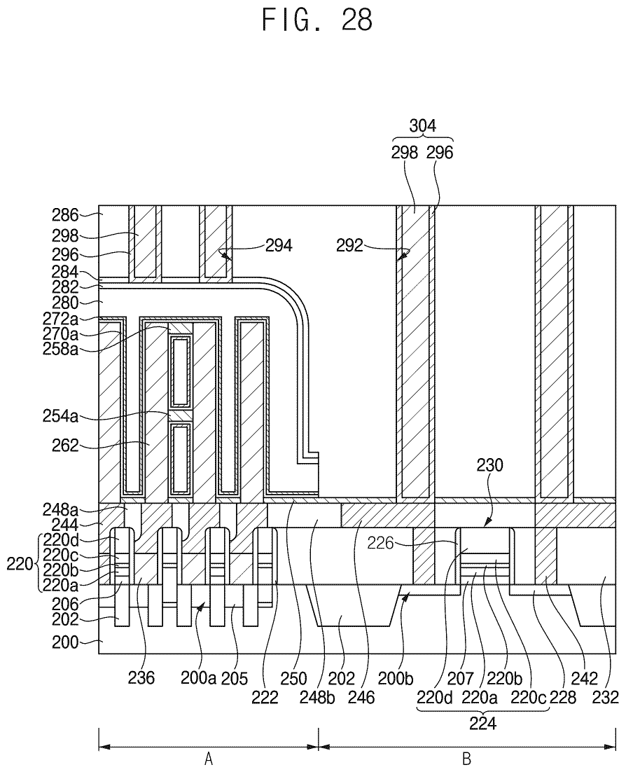

Referring to FIG. 27, a second insulating interlayer 286 may be deposited on the first plate pattern 280 and the first etch stop layer 250. The second insulating interlayer 286 may include a silicon oxide-based material. The second insulating interlayer 286 may include, e.g., a TEOS layer.

An upper surface of the second insulating interlayer 286 may be higher than an upper surface of the second etch stop pattern 284. The upper surface of the second insulating interlayer 286 may be substantially flat. In example embodiments, a planarization process of the upper surface of the second insulating interlayer 286 may be further performed. The planarization process may include, e.g., a chemical mechanical polishing process and/or an etch-back process.

Referring to FIG. 28, the second insulating interlayer 286 and the first etch stop layer 250 on the peripheral circuit region B may be etched to form first contact holes exposing the second conductive pattern 246. The second insulating interlayer 286 and the second etch stop pattern 284 on the cell region A may be etched to form second contact holes 294 exposing the upper metal pattern 282.

In some example embodiments, example embodiments, the second contact hole 294 may have a sidewall slope such that a width of the second contact hole 294 may decrease from an upper portion of the second contact hole 294 to a bottom of the second contact hole 294. The sidewall slope may be constant. Accordingly, the second contact hole 294 may have a lower width less than an upper width.

A second barrier metal layer may be formed on the surfaces of the first contact holes 292 and the second contact holes 294 and the second insulating interlayer 286. A second metal layer may be formed on the second barrier metal layer to fill the first contact holes 292 and the second contact holes 294.

The second barrier metal layer may include, e.g., titanium, titanium nitride, tantalum, tantalum nitride, etc. The second metal layer may include, e.g., tungsten. In some example embodiments, the second metal layer may include, e.g., aluminum, copper, ruthenium, cobalt, nickel, palladium, platinum, silver, or gold.

The second metal layer and the second barrier metal layer may be planarized until the upper surface of the second insulating interlayer 286 is exposed to form a preliminary barrier metal pattern 296 and a second metal pattern 298a. The planarization process may include, e.g., a chemical mechanical polishing process. The preliminary barrier metal pattern 296 and the second metal pattern 298a may be formed in each of the first contact holes 292 and the second contact holes 294.

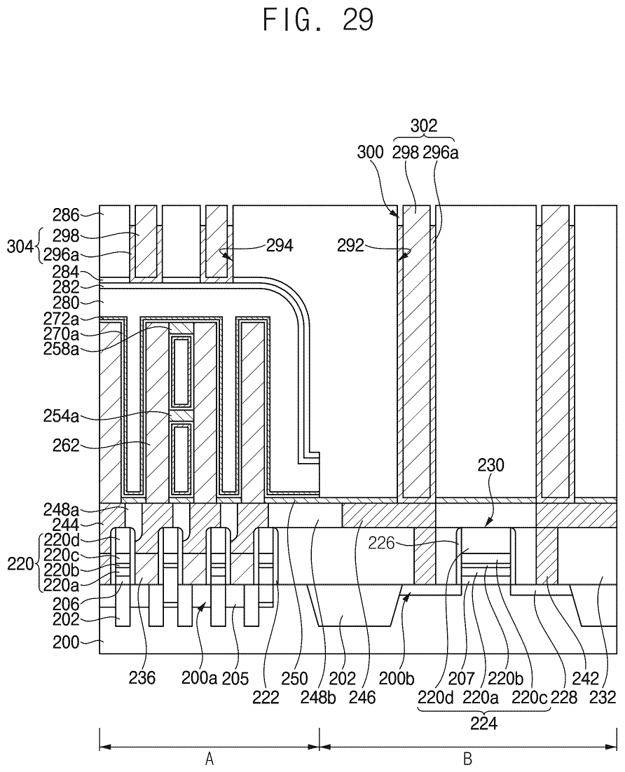

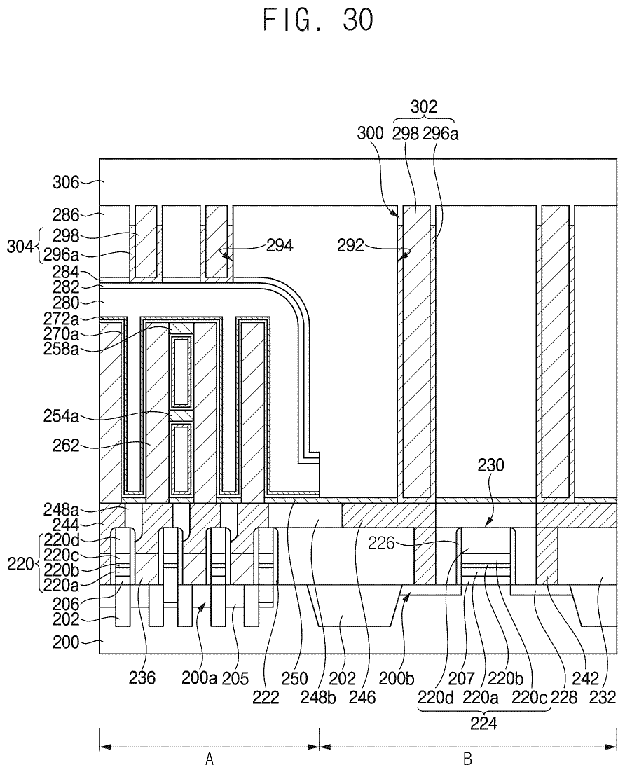

Referring to FIG. 29, an upper portion of the preliminary barrier metal pattern 296 may be partially etched to form a second barrier metal pattern 296a in each of the first contact hole 292 and the second contact hole 294.

Accordingly, a first contact plug 302 including the second barrier metal pattern 296a and the second metal pattern 298 may be formed in the first contact hole 292, and a second contact plug 304 including a second barrier metal pattern 296a and a second metal pattern 298 may be formed in the second contact hole 294.

In the first contact plug 302, an uppermost surface of the second barrier metal pattern 296a may be lower than an upper surface of the second metal pattern 298. Additionally, in the second contact plug 304, the uppermost surface of the second barrier metal pattern 296a may be lower than the upper surface of the second metal pattern 298. A first recess 300 may be formed between the second insulating interlayer 286 and the second metal pattern 298 above the upper surface of the second barrier metal pattern 296a.

Referring to FIG. 30, a third insulating interlayer 306 may be formed on the second insulating interlayer 286 and the first and second contact plugs 302 and 304 to fill the first recess 300. The third insulating interlayer 306 may cover the second insulating interlayer 286 and the first and second contact plugs 302 and 304. The same insulation material (e.g., the third insulating interlayer) may be formed in the first recess 300 and on the second insulating interlayer 286, and the first and second contact plugs 302 and 304.

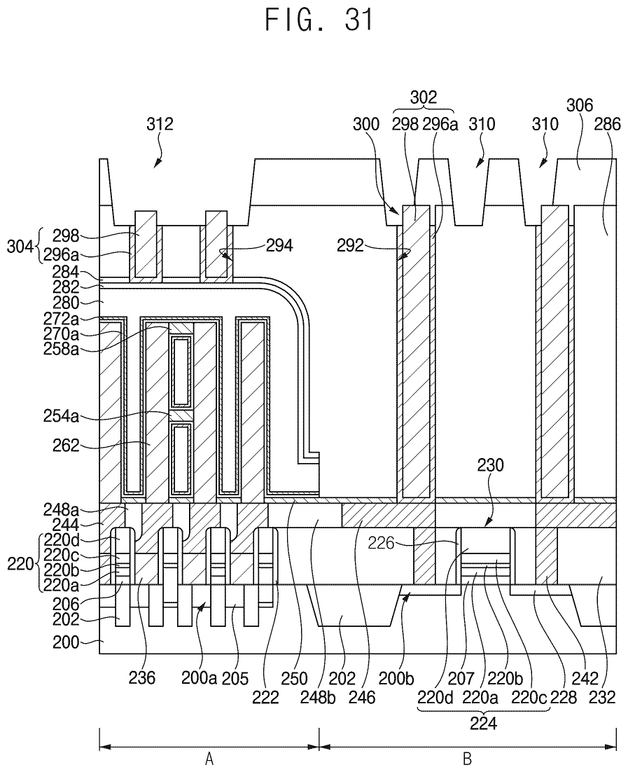

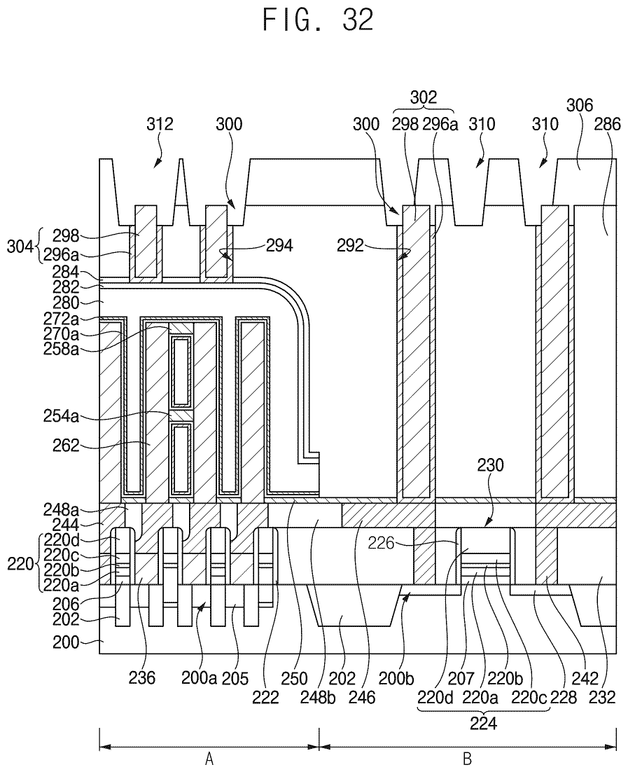

Referring to FIGS. 31 and 32, upper portions of the third insulating interlayer 306 and the second insulating interlayer 286 on the peripheral circuit region B may be etched to form a first opening 310 exposing at least a portion of the first contact plug 302. A portion of the third insulating interlayer 306 and the second insulating interlayer 286 on the cell region A may be etched to form a second opening 312 exposing at least a portion of the second contact plug 304.

The process for forming the first and second openings 310 and 312 may include a photo process and an etching process. The etching process may include, e.g., a dry etching process.

The first and second openings 310 and 312 may pass through the third insulating interlayer 306, and extend into a portion under the upper surface of the second insulating interlayer 286 in the vertical direction.

In example embodiments, in a plan view, each of the first and second openings 310 and 312 may have a line shape or a square shape extending in one direction.

In example embodiments, as shown in FIG. 31, a plurality of second contact plugs 304 arranged in the width direction may be exposed by a bottom of the second opening 312. In some example embodiments, as shown in FIG. 32, one second contact plug 304 in the width direction may be exposed by a bottom of the second opening 312. Each of the first and second openings 310 and 312 may have a sidewall slope such that a lower width of each of the first and second openings 310 and 312 is less than an upper width of each of the first and second openings 310 and 312.

In example embodiments, in each of the first and second openings 310 and 312, at least a portion lower than the upper surface of the second insulating interlayer 286 may have a sidewall slope such that a width is gradually decreased toward the bottom.

In the etching process for forming the first and second openings 310 and 312, the first and second contact plugs 302 and 304 may be hardly etched. Accordingly, the bottom of the first opening 310 exposing each of the first contact plugs 302 may be higher than the bottom of the first opening 310 exposing the second insulating interlayer 286, and the bottom of the second opening 312 exposing the second contact plugs 304 may be higher than the bottom of the second opening 312 exposing the second insulating interlayer 286.

In example embodiments, at least one first opening 310 may expose only the second insulating interlayer 286 may be disposed between the two first openings 310 exposing first contact plugs 302.

In example embodiments, at least one first opening 310 may be disposed between neighboring first contact plugs 302 in the horizontal direction. Only the second insulating interlayer 286 may be exposed by a lower sidewall of the first opening 310 disposed between the neighboring first contact plugs 302 in the horizontal direction.

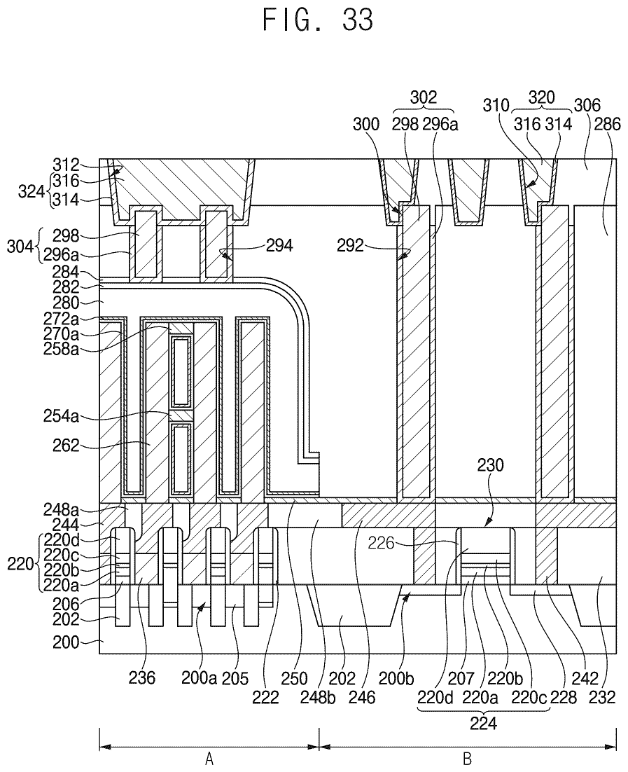

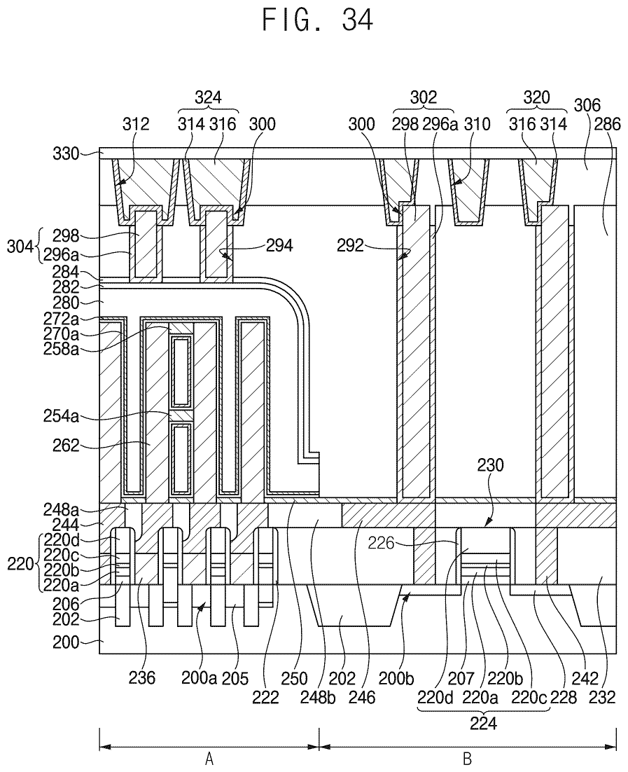

Referring to FIGS. 33 and 34, a third barrier metal layer may be conformally formed on sidewalls and on bottom surfaces of the first and second openings 310 and 312 and on the upper surface of the third insulating interlayer 306. A third metal layer may be formed on the third barrier metal layer to fill the first and second openings 310 and 312.

The third barrier metal layer may include, e.g., titanium, titanium nitride, tantalum, tantalum nitride, etc. In example embodiments, the third metal layer may include a material having a resistance lower than a resistance of the second metal pattern 298. For example, the third metal layer may include copper. In some example embodiments, the third metal layer may include aluminum, ruthenium, cobalt, nickel, palladium, platinum, silver, or gold.

Thereafter, the third metal layer and the third barrier metal layer may be planarized until an upper surface of the third insulating interlayer 306 is exposed to form a third barrier metal pattern 314 and a third metal pattern 316. The third barrier metal pattern 314 and the third metal pattern 316 may be formed in each of the first opening 210 and the second opening. The planarization process may include, e.g., a chemical mechanical polishing process and/or an etch-back process.

In example embodiments, as shown in FIG. 33, the second conductive pattern structure 324 may contact at least two second contact plugs 304 in the width direction. In this case, the semiconductor device shown in FIG. 18 may be manufactured by subsequent processes. In some example embodiments, as shown in FIG. 34, the second conductive pattern structure 324 may contact only one second contact plug 304 arranged in the width direction. In this case, the semiconductor device shown in FIG. 19 may be manufactured by subsequent processes.

The first conductive pattern structure 320 may include a first bottom surface contacting a first contact plug 302 and a second bottom surface contacting the second insulating interlayer 286. The second bottom surface of the first conductive pattern structure 320 may be lower than the first bottom surface of the first conductive pattern structure 320.

A portion of the first conductive pattern structure 320 positioned lower than the upper surface of the second insulating interlayer 286 is referred to in the following disclosure as a fourth portion, and the fourth portion of the first conductive pattern structure 320 and an upper sidewall of the first contact plug 302 may face toward each other in the horizontal direction. In the claims, the recitation of a “fourth portion” without more is not intended to incorporate this definition therein.

In example embodiments, the sidewall of the second metal pattern 298 may be positioned higher than the uppermost surface of the second barrier metal pattern 296a in the first contact plug 302, and the sidewall of the second metal pattern 298 and the fourth portion of the conductive pattern structure 320 may face toward each other in the horizontal direction.

Referring to FIGS. 19 and 20 again, a capping layer 330 may be formed on the first and second conductive pattern structures 320 and 324 and the third insulating interlayer 306. The capping layer 330 may cover upper surfaces of the first and second conductive patterns 320 and 324 and the third insulating interlayer 306. The capping layer 330 may include an insulation material, e.g., silicon nitride or silicon oxynitride.

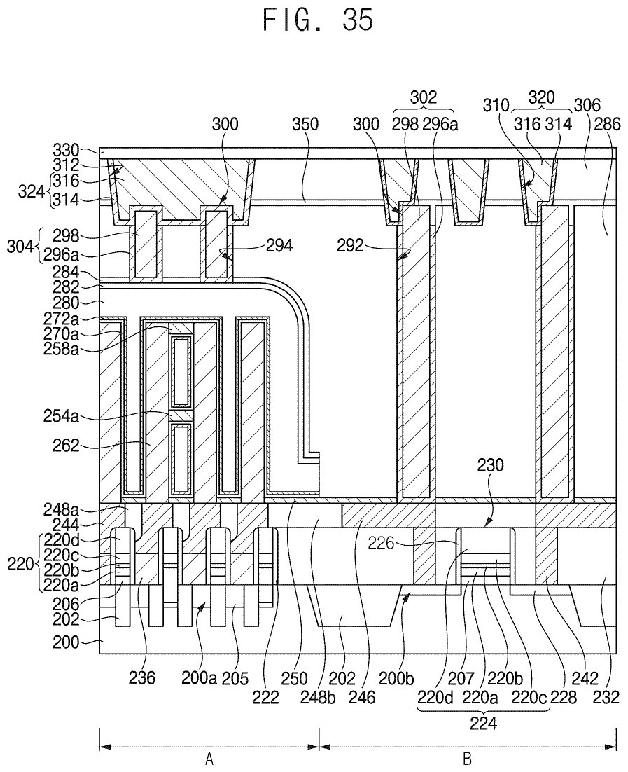

FIG. 35 is a cross-sectional view of a semiconductor device according to example embodiments.

The semiconductor device shown in FIG. 35 may be substantially the same as the semiconductor device shown in FIG. 19, except that an adhesive layer is further included.

Referring to FIG. 35, an adhesive layer 340 may occupy the first recess 300, and the adhesive layer 340 may further cover upper surfaces of the first and second contact plugs 302 and 304 and the second insulating interlayer 286. A third insulating interlayer 306 may be on the adhesive layer 340.

In example embodiments, voids may not be present in the adhesive layer 340 in the first recess 300. In some example embodiments, voids may be present in the adhesive layer 340 in the first recess 300.

Processes for manufacturing the semiconductor device shown in FIG. 35 may be substantially the same as processes as those described with reference to FIGS. 20 to 34, except for a process for forming the adhesive layer. First, the process described with reference to FIGS. 20 to 29 may be performed. Thereafter, before forming the third insulating interlayer 306, the adhesive layer 340 may be formed on the second insulating interlayer 286 and the first and second contact plugs 302 and 304 to fill the first recess 300. Thereafter, the processes described with reference to FIGS. 30 to 34 may be performed on the adhesive layer 340 to manufacture the semiconductor device.

The interconnection structure included in the semiconductor device may have high reliability, so the semiconductor device may have high reliability.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A semiconductor device, comprising:
a substrate;
a first insulating interlayer on the substrate;
a plurality of first contact plugs passing through the first insulating interlayer, each of the plurality of first contact plugs including:
a first metal pattern; and
a first barrier metal pattern covering a portion of a sidewall of the first metal pattern and further covering a bottom of the first metal pattern, and the first barrier metal pattern further exposing an upper sidewall of the first metal pattern;
a second insulating interlayer that is on the first insulating interlayer and is further on the plurality of first contact plugs; and
a plurality of first conductive patterns passing through the second insulating interlayer and extending below an upper surface of the first insulating interlayer in a vertical direction, each of the plurality of first conductive patterns having:
a first bottom surface contacting a portion of an upper surface of a respective first contact plug of the plurality of first contact plugs; and
a second bottom surface contacting the first insulating interlayer and being lower than the first bottom surface.

2. The semiconductor device of claim 1, wherein an upper surface of the first insulating interlayer and an upper surface of the first metal pattern are coplanar with each other, and a first recess is between the first insulating interlayer and the first metal pattern.

3. The semiconductor device of claim 2, wherein the second insulating interlayer occupies the first recess.

4. The semiconductor device of claim 2, further comprising an adhesive layer that is between the first insulating interlayer and the second insulating interlayer and is further between the plurality of first contact plugs and the second insulating interlayer, and
wherein the adhesive layer occupies the first recess.

5. The semiconductor device of claim 1, wherein an uppermost surface of the first barrier metal pattern is lower than an upper surface of the first metal pattern, and
wherein each of the plurality of first conductive patterns contacts each of:
the upper surface of the first metal pattern;
the upper sidewall of the first metal pattern; and
an upper surface of the first barrier metal pattern.

6. The semiconductor device of claim 1, wherein the second bottom surface of each first conductive pattern is coplanar with or lower than an upper surface of the first barrier metal pattern of the respective first contact plug.

7. The semiconductor device of claim 1, wherein at least a portion of each first conductive pattern is lower than the upper surface of the first insulating interlayer and faces the upper sidewall of the first metal pattern of the respective first contact plug in a horizontal direction.

8. The semiconductor device of claim 1, wherein each of the first conductive patterns has a sidewall slope such that a lower width of the first conductive pattern is less than an upper width of the first conductive pattern.

9. The semiconductor device of claim 1, wherein a distance in a horizontal direction between an uppermost sidewall of the first metal pattern of the respective first contact plug and the first conductive pattern is greater than a distance in the horizontal direction between the uppermost sidewall of the first barrier metal pattern of the respective first contact plug and the first conductive pattern.

10. The semiconductor device of claim 1, wherein the second insulating interlayer includes a silicon oxide-based material having a dielectric constant lower than a dielectric constant of the first insulating interlayer.

11. The semiconductor device of claim 1, further comprising a capping layer covering the plurality of first conductive patterns and further covering the second insulating interlayer.

12. A semiconductor device, comprising:
a substrate;
a first insulating interlayer on the substrate, the first insulating interlayer including a plurality of contact holes;
a plurality of first contact plugs in the plurality of contact holes, respectively, each first contact plug including:
a first metal pattern; and
a first barrier metal pattern covering a portion of a sidewall of the first metal pattern and further covering a bottom of the first metal pattern, and an uppermost surface of the first barrier metal pattern being lower than an upper surface of the first metal pattern;
a second insulating interlayer that is on the first insulating interlayer and is further on the plurality of first contact plugs; and
a plurality of first conductive patterns passing through the second insulating interlayer and extending below an upper surface of the first insulating interlayer in a vertical direction, and each of the plurality of first conductive patterns contacting an upper surface of a respective first contact plug of the plurality of first contact plugs and further contacting a respective upper portion of the first insulating interlayer,
wherein a distance in a horizontal direction between an uppermost sidewall of the first metal pattern of the respective first contact plug and the first conductive pattern is greater than a distance in the horizontal direction between an uppermost sidewall of the first barrier metal pattern of the respective first contact plug and the first conductive pattern.

13. The semiconductor device of claim 12, wherein at least a portion of each first conductive pattern is lower than the upper surface of the first insulating interlayer and faces the first metal pattern of the respective first contact plug in a horizontal direction.

14. The semiconductor device of claim 12, wherein the upper surface of the first insulating interlayer and the upper surface of the first metal pattern are coplanar with each other, and a first recess is between the first insulating interlayer and the first metal pattern.

15. The semiconductor device of claim 14, wherein the second insulating interlayer occupies the first recess.

16. The semiconductor device of claim 12, wherein the second insulating interlayer includes a silicon oxide-based material having a dielectric constant lower than a dielectric constant of the first insulating interlayer.

17. The semiconductor device of claim 12, wherein each of the plurality of first conductive patterns includes a first bottom surface contacting a portion of an upper surface of the respective first contact plug, and a second bottom surface contacting the first insulating interlayer and being lower than the first bottom surface.

18. A semiconductor device, comprising:
a substrate;
a plurality of capacitors on a cell region of the substrate;
a plurality of peripheral circuit patterns on a peripheral circuit region of the substrate;
a first insulating interlayer covering the plurality of capacitors and further covering the plurality of peripheral circuit patterns;
a plurality of first contact plugs passing through the first insulating interlayer and connecting to the plurality of peripheral circuit patterns, each of the plurality of first contact plugs including:
a first metal pattern; and
a first barrier metal pattern covering a portion of a sidewall of the first metal pattern and further covering a bottom of the first metal pattern, and the first barrier metal pattern further exposing an upper sidewall of the first metal pattern;
a second insulating interlayer that is on the first insulating interlayer and is further on the plurality of first contact plugs; and
a first conductive pattern passing through the second insulating interlayer and extending below an upper surface of the first insulating interlayer in a vertical direction, and the first conductive pattern contacting upper surfaces of the plurality of first contact plugs and further contacting an upper surface of the first insulating interlayer on the peripheral circuit region,
wherein a distance in a horizontal direction between an uppermost sidewall of the first metal pattern of a first contact plug of the plurality of first contact plugs and the first conductive pattern is greater than a distance in the horizontal direction between an uppermost sidewall of the first barrier metal pattern of the first contact plug and the first conductive pattern.

19. The semiconductor device of claim 18, further comprising:
a plurality of second contact plugs passing through the first insulating interlayer and electrically connecting to respective capacitors of the plurality of capacitors, each of the plurality of second contact plugs including:
a first metal pattern; and
a first barrier metal pattern covering a portion of a sidewall of the first metal pattern and further covering a bottom of the first metal pattern, and the first barrier metal pattern further exposing an upper sidewall of the first metal pattern; and
second conductive patterns contacting an upper surface of each of the plurality of second contact plugs and contacting an upper surface of the first insulating interlayer on the cell region.

20. The semiconductor device of claim 18, wherein the second insulating interlayer includes a silicon oxide-based material having a dielectric constant lower than a dielectric constant of the first insulating interlayer.
